(19) United States
(12) Patent Application Publication
(10) Pub. No.: US 2025/0294915 A1
(43) Pub. Date: Sep. 18, 2025

(54) MXene Optoelectronic Systems And Devices

(71) Applicants: Drexel University, Philadelphia, PA (US); Worcester Polytechnic Institute, Worcester, MA (US); NanoGrass Solar, LLC, Philadelphia, PA (US)

(72) Inventors: Bahram Nabet, Philadelphia, PA (US); Pouya Dianat, Chicago, IL (US); Kiana Montazeri, Philadelphia, PA (US); Michel W. Barsoum, Moorestown, NJ (US); Lyubov Titova, Worcester, MA (US)

(21) Appl. No.: 19/080,116

(22) Filed: Mar. 14, 2025

Related U.S. Application Data
(63) Continuation of application No. 17/474,604, filed on Sep. 14, 2021, now abandoned.
(60) Provisional application No. 63/077,966, filed on Sep. 14, 2020.

(51) Int. Cl. H10F 77/20; H10D 62/85; H10D 64/62; H10F 30/227; H10F 30/28; H10F 30/282; H10F 77/124

(52) U.S. Cl. CPC H10F 77/244; H10D 62/85; H10D 64/62; H10F 30/2275; H10F 30/282; H10F 30/283; H10F 77/1248

(57) ABSTRACT

Provided herein are MXene-containing photodetectors and related methods. Also provided are MXene-containing THz polarizers as well as MXene-containing MOSFETs, MESFETs, and HEMFETs.

### CROSS-REFERENCE TO RELATED APPLICATIONS

This application is a continuation of U.S. patent application Ser. No. 17/474,604, “MXene Optoelectronic Systems and Devices” (filed Sep. 14, 2021), claims priority to and the benefit of U.S. Provisional Application No. 63/077,966, “MXene Optoelectronic Systems and Devices” (filed Sep. 14, 2020). All foregoing applications are incorporated herein by reference in their entireties for any and all purposes.

### GOVERNMENT RIGHTS

This invention was made with government support under 1904171 awarded by the National Science Foundation ICORPS; DMR 1740795 awarded by National Science Foundation; and DESC0012704 awarded by the Department of Energy. The government has certain rights in the invention.

### TECHNICAL FIELD

The present disclosure relates to the field of MXene materials and to the field of optoelectronic devices.

### BACKGROUND

Photodetectors have a wide range of applications and are presently in great demand due to the explosion in information, data transport, and processing needs, that is facilitated by fiber optics tele/data communications. In particular, high bandwidth is essential for data center operations supporting applications such as Internet of things (IoT), autonomous vehicles, artificial intelligence, and virtual reality among other Internet demands. The need for high-speed, high-responsivity detection is traditionally met by p-type-intrinsic-n-type (PIN) photodiodes, avalanche photodiodes (APD), metal-semiconductor-metal (MSM), or metal-graphene-metal photodetectors. For all these devices, high responsivity requires larger absorption areas. However, increasing a device's surface area limits its bandwidth both by increasing the RC time constants, and transit times of the optically generated carriers to the collection electrodes. A tradeoff therefore needs to be engineered depending on application.

Inherent anisotropic conductivity of 1D nanostructures such as semiconducting or metallic nanowires, or carbon nanotubes, has motivated efforts to design THz polarizers based on highly aligned nanowire or nanotube arrays. These structures achieve high performance characteristics, and, in the case of semiconductor nanowires, are dynamically switchable. However, achieving high degrees of alignment of nanowires or nanotubes over macroscopic regions remains challenging.

Accordingly, there is a long-felt need in the art for improved photodetector devices and THz polarizers.

### SUMMARY

2D transition metal carbides, known as MXenes, can be transparent when thin enough. They are also excellent electrical conductors with metal-like carrier concentrations. Herein, these characteristics are exploited to replace gold (Au) in GaAs photodetectors. By simply spin-coating trans-parent Ti3C2-based MXene electrodes from aqueous suspensions onto GaAs patterned with a photoresist and lifted off with acetone, photodetectors that outperform more standard Au electrodes are fabricated. Both the Au-and MXene-based devices show rectifying contacts with comparable Schottky barrier heights and internal electric fields. The latter, however, exhibit significantly higher responsivities and quantum efficiencies, with similar dark currents, hence showing better dynamic range and detectivity, and similar sub-nanosecond response speeds compared to the Au-based devices. The simple fabrication process is readily integrable into microelectronic, photonic-integrated circuits and silicon photonics processes, with a wide range of applications from optical sensing to light detection and ranging and telecommunications.

Metal-Semiconductor (MS) contacts are frequently used in connecting an (opto) electronic device to the external world, and MS contact properties are thus relevant aspects of all electronics. MS contacts can generally be classified in the two categories of (a) Ohmic, or linear, and (b) Schottky, or rectifying, contacts.

Certain characteristics of the disclosed MXene-semiconductor contacts that make devices based on them unique both in Ohmic and Schottky/rectifying behavior. Without being bound to any particular theory, this is because of the layered structure of MXenes, where charge transport in MS case occurs in-between layers (which do not have strong bonds) rather than along the layers. Furthermore, drop-cast, or spun-on MXene does not make chemical bonds to the semiconductor, as is the case of deposited metal, rather van der Waals (vdW) junctions are made that include an airgap between MXene and semiconductors. These differences are important for both Schottky and Ohmic contacts and are not obvious to a person skilled in the art. The disclosed devices are focused on MXene-Semiconductor (MX-S) Schottky contacts, one can also use the unique properties of MXenes for Ohmic contacts as well.

A “MX-S-MX” (MXene-semiconductor-MXene) photodetector (PD) device can comprise two back-to-back Schottky contacts disposed on GaAs, and such devices outperform similar ones using Au/Ti (or other metals) in terms of requisite Schottky characteristics of having a barrier and an electric field in GaAs and the like. Other devices (Barrier-enhanced MXene-semiconductor-MXene, termed “MX-S-MX/BE”) disclosed herein provide additionally improved characteristics.

Herein we report fabrication of terahertz, THz, polarizers by simply spin casting two dimensional, 2D, MXene Ti₃C₂T_{z} nanosheets on a photolithographically patterned THz-transparent substrate, and subsequent immersion in acetone. Lines 30 nm-thick and 10-20 μm wide result in electric field, E, extinction ratios of up to 3 dB, or power extinction ratios of up to 6 dB. Simulations show the possibility of achieving E extinction ratios beyond 16 dB, or power extinction ratio higher than 32 dB by increasing the thickness of the MXene lines to 1.5-2 μm and optimizing the metasurface patterns. The Ti₃C₂T_{z} nanosheets are solution-processed and can be deposited on a variety of substrates, including flexible ones. Chemically stable THz polarizers that combine high performance and low production costs can be readily manufactured, with characteristics that compare favorably with the much more involved metallic wire grids polarizers, including gold and tungsten. Moreover, recent demonstration of dynamic tunability of Ti₃C₂T_{z} THz conductivity by ultrafast optical pulses opens the possibility of using MXene wire-grids in high-speed THz modulators. Also provided herein are MXene-containing MOSFETs, MESFETs, and HEMFETs.

Additional devices are provided in which the MXene electrodes are disposed on a multilayered substrate.

In meeting these long-felt needs, the present disclosure provides photodetectors, comprising: an assembly that comprises (i) a semiconducting substrate having a surface; (ii) a first portion of MXene material superposed on the surface of the semiconducting substrate so as to define a Schottky contact between the first portion of MXene material and the semiconducting substrate; and (iii) a second portion of MXene material superposed on the surface of the semiconducting substrate so as to define a Schottky contact between the second portion of MXene material and the semiconducting substrate, the first portion of MXene material and the second portion of MXene material being separated by a distance.

Without being bound to any particular theory, one can incorporate a layered-structure of the semiconductor (i.e., the semiconducting substrate) that can (a) increase the MXene-Semiconductor barrier height thus reduces dark current and noise; (b) introduce a reservoir of confined high mobility charge to quickly capture and collect optically generated carriers; and/or (c) incorporate a region of extremely fast recombination centers made of low-temperature grown GaAs (LT-GaAs).

Again without being bound to any particular theory, the disclosed devices have achieved very low dark current in the sub-nA range, high speed in a few picosecond range and very high responsivity, detectivity and dynamic range, as well as very low noise equivalent power.

Also provided are methods, comprising collecting a photocurrent from a photodetector according to the present disclosure.

Further disclosed are methods, comprising: disposing a MXene material onto a surface of a semiconductor substrate so as to define a first region of the MXene material and a second region of the MXene material, the first region of the MXene material being separated from the second region of the MXene material by a distance in the range of from about 0.1 to about 50 micrometers.

Also disclosed are polarizers, comprising: a substrate; a plurality of parallel elongate MXene portions disposed on the substrate; the MXene portions having an average width and being arranged in an essentially periodic pattern, and adjacent MXene portions being separated from one another by an average separation distance of from about 0.1 to about 100 micrometers and all intermediate values.

Further provided are methods, comprising: disposing a MXene material onto a surface of a semiconductor substrate so as to define a plurality of parallel elongate MXene portions disposed on the substrate; the MXene portions having an average width and being arranged in an essentially periodic pattern, and adjacent MXene portions being separated from one another by an average separation distance of from about 0.1 to about 100 micrometers.

Also provided are metal semiconductor field effect transistors, comprising: a source electrode; a drain electrode; and a gate electrode, a resistive path channel being defined between the source electrode and the gate electrode, the gate electrode comprising a MXene material configured to perform as a rectifying Schottky contact, the MXene material of the gate electrode being essentially transparent, and the metal semiconductor field effect transistor being configured as an optical field effect transistor controllable by illumination of the MXene material.

Also disclosed are high electron mobility field effect transistors, comprising: a source electrode; a drain electrode; a gate electrode; and a resistive path channel being defined between the source electrode and the gate electrode, the resistive path channel comprising a heterojunction, the gate electrode comprising a MXene material configured to perform as a rectifying Schottky contact, the MXene material being essentially transparent, and the high electron mobility field effect transistor being configured as an optical field effect transistor controllable by illumination of the MXene material.

Additionally provided are metal oxide semiconductor field effect transistors, comprising: a source electrode; a drain electrode; a gate electrode; and a resistive path channel being defined between the source electrode and the gate electrode, one or more of the source electrode, the gate electrode, and the drain electrode comprising a MXene material configured to perform as an ohmic contact, the MXene material optionally being essentially transparent.

Further provided are photodetectors, comprising: an assembly that comprises (i) a first semiconducting substrate having a first surface and a second surface; (ii) a first portion of MXene material superposed on a first surface of the semiconducting substrate so as to define a contact between the first portion of MXene material and the first surface of the first semiconducting substrate; and (iii) a second portion of MXene material superposed on the first surface of the first semiconducting substrate so as to define a contact between the second portion of MXene material and the first surface of the first semiconducting substrate, the first portion of MXene material and the second portion of MXene material being separated from one another by a distance.

Also provided are methods, comprising collecting a photocurrent from a photodetector according to the present disclosure, e.g., according to any one of Aspects 1-17.

Additionally disclosed are polarizers, comprising: a substrate; a plurality of parallel elongate MXene portions disposed on the substrate; the MXene portions having an average width and being arranged in an essentially periodic pattern, and adjacent MXene portions being separated from one another by an average separation distance of from about 0.1 to about 100 micrometers, e.g., from about 0.1 to about 100 micrometers, from about 1 to about 90 micrometers, from about 2 to about 80 micrometers, from about 4 to about 70micrometers, from about 6 to about 60 micrometers, from about 10 about 50 micrometers, or from about 15 to about 30 micrometers.

Also provided are metal semiconductor field effect transistors, comprising: a source electrode; a drain electrode; and a gate electrode, a resistive path channel being defined between the source electrode and the gate electrode, the gate electrode comprising a MXene material configured to perform as a rectifying Schottky contact, the MXene material of the gate electrode being essentially transparent, and the metal semiconductor field effect transistor being configured as an optical field effect transistor controllable by illumination of the MXene material.

Further disclosed are high electron mobility field effect transistors, comprising: a source electrode; a drain electrode; a gate electrode; and a resistive path channel being defined between the source electrode and the gate electrode, the resistive path channel comprising a heterojunction, the gate electrode comprising a MXene material configured to perform as a rectifying Schottky contact, the MXene material being essentially transparent, and the high electron mobility field effect transistor being configured as an optical field effect transistor controllable by illumination of the MXene material; and a first semiconducting substrate on which the gate electrode is superposed, optionally a second semiconducting substrate on which the first semiconducting substrate is disposed, the second semiconducting substrate defining a heterojunction with the first semiconducting substrate and the first semiconducting substrate has a bandgap energy (Eg) greater than a bandgap energy (Eg) of the second semiconducting substrate.

Additionally provided are metal oxide semiconductor field effect transistors, comprising: a source electrode; a drain electrode; a gate electrode; and a resistive path channel being defined between the source electrode and the gate electrode, one or more of the source electrode, the gate electrode, and the drain electrode comprising a MXene material configured to perform as an ohmic contact, the MXene material optionally being essentially transparent; and a first semiconducting substrate on which the gate electrode is superposed, optionally a second semiconducting substrate on which the first semiconducting substrate is disposed, the second semiconducting substrate defining a heterojunction with the first semiconducting substrate and the first semiconducting substrate has a bandgap energy (Eg) greater than a bandgap energy (Eg) of the second semiconducting substrate.

### BRIEF DESCRIPTION OF THE DRAWINGS

The file of this patent or application contains at least one drawing/photograph executed in color. Copies of this patent or patent application publication with color drawing(s)/photograph(s) will be provided by the Office upon request and payment of the necessary fee.

In the drawings, which are not necessarily drawn to scale, like numerals can describe similar components in different views. Like numerals having different letter suffixes can represent different instances of similar components. The drawings illustrate generally, by way of example, but not by way of limitation, various aspects discussed in the present document. In the drawings:

FIGS. 1A-1I provide fabrication process and energy band diagrams for MXene-GaAs-MXene (MX-S-MX) photodetector devices. (FIG. 1A, 1B) Preparation of MXene colloidal suspension. In (FIG. 1C) and (FIG. 1D), conventional photolithography is performed resulting in exposed areas for contact deposition. (FIG. 1E) MXene aqueous colloidal suspension is spin-coated, and (FIG. 1F) lifted off by immersion in acetone. (FIG. 1G) SEM of the final device showing cathode-anode separation gap. (FIG. 1H) Sketch of the energy band diagram of device under moderate bias—showing the Schottky contacts at cathode and anode, the barrier height, built-in voltage, internal field, and depletion regions. FIG. 1I) Same as (1H), but under high biasing voltage resulting in flat-band conditions.

FIGS. 2A-2C—Optical properties of the Ti₃C₂ film with nominal thickness of 19.2 nm compared to the silica baseline. (FIG. 2A) Measured transmission; and (FIG. 2B) reflection spectra. (FIG. 2C) Absorptance=1−(reflectance+transmittance). Inset in (FIG. 2C) shows a silica substrate half of which was covered and used for comparison. Wide spectral opacity and nearly 30% absorptance from 350-2200 nm in addition to high absorptance in UV range are notable.

FIGS. 3A-3H provide a comparison of current-voltage characteristics of MXene-GaAs-MXene (MX-S-MX) and conventional Ti/Au—GaAs—Ti/Au (MSM) photodetectors with gap spacing of 10 μm. (FIG. 3A) Confocal microscopy image of the fabricated MX-S-MX photodetector with an overlay of the laser spot size, and 3E) the same but for MSM. (FIGS. 3B-3D) Current-voltage responses of MX-S-MX to 532, 780, and 830 nm wavelength light, respectively. (FIGS. 3F-3H) The same as (FIG. 3B)-(FIG. 3D), respectively, but for the MSM device.

FIGS. 4A-4H provide a comparison of MX-S-MX (FIG. 4A) (left column) and MSM (FIG. 4E) (right column) detectors' photocurrent under various optical intensities and at different biases and with gap spacing of 10 μm. Top row: (FIGS. 4B, 4F) response to λ=532 nm incident light. Middle row: (FIGS. 4C, 4G) λ=780 nm. Bottom row: (FIGS. 4D, 4H) λ=830 nm. MX-S-MX detector outperforms the Ti/Au-based device with up to 300% more responsivity at all measured wavelengths, most significantly at λ=830 nm.

FIGS. 5A-5B provide a comparison of the temporal response of MXene-and Ti/Au-based devices to excitation by 100 fs pulses of 830 nm light at 8 V bias under various indicated optical powers. (FIG. 5A) MXene device pulse response; inset shows same data normalized to peak amplitude. (FIG. 5B) Same as (FIG. 5A) for Ti/Au MSM. Pulse width, rise time, and fall times are indicated for 300 μW optical power.

FIGS. 6A-6D provide current-voltage characteristics of MX-S-MX photodetector in dark and under 532 nm light with different contacts gap size of (FIG. 6A), 5 um, (FIG. 6B), 15 um, and (FIG. 6C), 35 um. Top insets are corresponding pictures of the devices. Optical response is almost identical regardless of gap width, indicating that response is dependent only on the properties of cathode region. (FIG. 6D), Electrode transparency: I-V characteristics of MX-S-MX device when outer corner of a contact, pointed by red arrow, is illuminated by a 532 nm light spot. Compared to dark, a factor of nearly 400 increase in current is observed.

FIGS. 7A-7H provide a comparison of quantum efficiency of MXene-GaAs-MXene (MX-S-MX) and conventional Ti/Au—GaAs—Ti/Au (MSM) photodetectors. (FIG. 7A), Confocal microscope image of the fabricated MX-S-MX photodetector illuminated by a laser spot. (FIG. 7E), The same but for MSM. (FIG. 7B, FIG. 7C, FIG. 7D), quantum efficiency of MX-S-MX to 532, 780, and 830 nm wavelength light, respectively. FIG. 7F, FIG. 7G, FIG. 7H, are the same as FIG. 7B, FIG. 7C, FIG. 7D, respectively, but for MSM device. MXene has significantly higher quantum efficiency, particularly at 830 nm.

FIGS. 8A-8B provide temporal characteristics of MX-S-MX (red) compared to Ti/Au (blue) detector. (FIG. 8A), pulse width, (FIG. 8B,) fall time.

FIGS. 9A-9J provide a fabrication process of MXene wire-grid polarizer. (FIG. 9A, FIG. 9B) Preparation of MXene colloidal suspension. In (FIG. 9C) and (FIG. 9D), conventional photolithography is performed resulting in exposed areas for striations. (FIG. 9E) MXene aqueous colloidal suspension is spin-coated, and (FIG. 9F) lifted off by immersion in acetone. (FIG. 9G) AFM of a striation edge. (FIG. 9H) optical image of the final device and SEM close-up of striations. FIG. 9I provides data showing transmitted pulses, normalized to peak value. FIG. 9J provides data showing transmitted pulses, normalized to peak value.

FIGS. 10A-10B (FIG. 10A) Schematic diagram of experiment: Incident THz pulse is focused to a ˜1.5 mm spot on the polarizer using an off-axis polarizer; another polarizer collects the transmitted pulse, which goes through a commercial wire-grid polarizer before being detected. (FIG. 10B) Linearly polarized THz pulse is normally incident on a MXene polarizer, which can be rotated around the normal; only a component that is parallel to the incident pulse polarization is detected.

FIGS. 11A-11B (FIG. 11A) Reference THz waveform (transmitted through air), and THz waveforms transmitted through quartz substrate and through one of the polarizer devices (K5) with lines oriented along incident THz polarization. (FIG. 11B) Corresponding THz amplitude as a function of frequency.

FIGS. 12A-12D-Peak of transmitted THz pulses, normalized to its value for θ=0°, as a function of θ, for polarizer structures (FIG. 12A) K1, (FIG. 12B) K2 (FIG. 12C) K3 and (FIG. 12D) K4. Symbols show experimental data, and lines—Malus's law fits.

FIGS. 13A-13D provide transmitted THz pulses in time domain for incident THz pulse polarization parallel and perpendicular to the lines, for polarizer structures K1 (FIG. 13A), K2 (FIG. 13B), K3 (FIG. 13C), and K4 (FIG. 13D). Reference THz pulses transmitted through the quartz substrate are also shown.

FIGS. 14A-14B (FIG. 14A) Electric field extinction ratio and (FIG. 14B) insertion losses for four THz polarizer devices.

FIGS. 15A-15F-Simulated ER (FIG. 15A, FIG. 15C, FIG. 15E) and IL (FIG. 15B, FIG. 15D, FIG. 15F) at 1 TH z as a function of fill factor (FIG. 15A, FIG. 15B), period (FIG. 15C, FIG. 15D) and thickness (FIG. 15E, FIG. 15F). Parameters that were fixed in a simulation are given in the top panels (FIG. 15A, FIG. 15D, FIG. 15E).

FIG. 16 provides images of four polarizer patterns tested herein.

FIGS. 17A-17F illustrates spincast and lift off of various concentration of solids in Ti3C2Tz, (FIG. 17A) Spin cast was performed in 30 seconds with 800 rpm rotation speed. SEM images of the resulting striations with spacing s=4 μm spacing between the lines for (FIG. 17B) 3.4 g/L, (FIG. 17C) 6 g/L, (FIG. 17D) 8 g/L, (FIG. 17E) 15.1 g/L, and (FIG. 17F) 23 g/L concentration.

FIG. 18-Insertion loss of a quartz substrate. Symbols-experimental points calculated from data in FIG. 2(B), line—guide to the eye. At 1 THz, the insertion loss is ˜0.6 dB, in agreement with predicted value due to air-quartz reflection, given n_{quartz}=2.156. At frequencies>1.8 THz, impurity absorption and higher-lying phonon modes contribute to the measured insertion loss.

FIGS. 19A-19C (FIG. 19A) FDTD simulation geometry of MXene polarizer. PML is perfect matched layer. PML 1 acts as a THz wave input, and PML 2 as THz wave output. (FIG. 19B), (FIG. 19C) Electrical field distribution in x-y plane (FIG. 19B) and x-z plane (FIG. 19C) when the polarization of the incident THz wave incident makes a 45 degree angle with the x-axis.

FIG. 20—Complex THz conductivity (solid symbols represent real and open symbols—imaginary conductivity components; lines show a global fit of both components to the Drude-Smith model with fit parameters given in the legend.

FIGS. 21A-21D (FIG. 21A) The planar band structure along the surface at 0 V bias, (FIG. 21B) Optical microscope image of the surface of the MX-S-MX detector on AlGaAs, (FIG. 21C) Layered structure of the MX-S-MX/BE photodetector, (FIG. 21D) The energy band diagram of the vertical layered structure.

FIGS. 22A-22F (FIG. 22A) a synthesis of 32 MXene from etching the A layer in MAX phase precursor. (FIG. 22B) The structure of the fabricated device on a layered wafer comprised of GaAs/AlGaAs heterostructure and low temperature grown GaAS. An optical microscope image of the top view of the device is shown. (FIG. 22C) Energy band diagram of MX-S-MX/BE device without applied bias, (FIG. 22D) Energy band diagram of MX-S-MX/BE under small to moderate applied bias. The sketch depicts the below reach through state, where the depletion width at the cathode extends. (FIG. 22E) Energy band diagram of the MX-S-MX/BE device at reach through, where the depletion regions from each electrode reaches to a common point. (FIG. 22F) energy band diagram under high bias, also known as flat band state.

FIGS. 23A-23B (FIG. 23A) Log scale comparison of the dark currents. MX-S-MX/BE detector shows up to two orders of magnitude lower dark current at around 122 pA. (FIG. 23B) Linear scale comparison of the dark currents of GaAs and MX-S-MX/BE detectors. Inset shows the linear scale dark current characteristic of MX-S-MX/BE device.

FIGS. 24A-24F (FIG. 24A) I-V curves under various optical powers from a continuous wave laser, (FIG. 24B) I-V curves under various optical powers from a picosecond pulse laser, (FIG. 24C) Photocurrent versus optical power characteristics of the MX-S-MX/BE photodetector under sweeping biasing voltages with CW laser, (FIG. 24D) Photocurrent versus optical power characteristics of the MX-S-MX/BE photodetector under sweeping biasing voltages with ps pulse laser, (FIG. 24E) External quantum efficiency of the detector under various biasing voltages, using CW laser source, calculated from the optical response, (FIG. 24F) External quantum efficiency of the detector under various biasing voltages, using ps pulse laser source, calculated from the optical response.

FIGS. 25A-25F (FIG. 25A) Optoelectronic time response of the MX-S-MX/BE detector a normalized impulse response under 290 power at 8 V bias, (FIG. 25B) normalized impulse response under 290 power at 10 V bias, (FIG. 25C) normalized impulse response under 214 power at 10 V bias, (FIG. 25D) FWHM of the responses under sweeping bias from 0 to 10 V, (FIG. 25E) fall time measurements of the impulse response under sweeping bias from 4 to 10 V at 30 and 90 incoming power, (FIG. 25F) fall time characteristic of the impulse response at 290 power from 2 to 10 V biasing voltage.

FIGS. 26A-26B (FIG. 26A) responsivity of the MX-S-MX/BE photodetector at 2-10 V biasing voltages, under sweeping power at 800 nm wavelength, sourced from a Picosecond pulse laser, (FIG. 26B) Continuous wave laser.

FIGS. 27A-27B (FIG. 27A) Energy band diagram for a component according to the present disclosure under no bias; (FIG. 27B) Energy band diagram for a component according to the present disclosure under applied bias.

FIG. 28 provides an energy band diagram of a High Electron Mobility Transistor device with a transparent MXene Schottky (van der Waals) gate.

### DETAILED DESCRIPTION OF ILLUSTRATIVE EMBODIMENTS

The present disclosure may be understood more readily by reference to the following detailed description of desired embodiments and the examples included therein.

Unless otherwise defined, all technical and scientific terms used herein have the same meaning as commonly understood by one of ordinary skill in the art. In case of conflict, the present document, including definitions, will control. Preferred methods and materials are described below, although methods and materials similar or equivalent to those described herein can be used in practice or testing. All publications, patent applications, patents and other references mentioned herein are incorporated by reference in their entirety. The materials, methods, and examples disclosed herein are illustrative only and not intended to be limiting.

The singular forms “a,” “an,” and “the” include plural referents unless the context clearly dictates otherwise.

As used in the specification and in the claims, the term “comprising” can include the embodiments “consisting of” and “consisting essentially of.” The terms “comprise(s),” “include(s),” “having,” “has,” “can,” “contain(s),” and variants thereof, as used herein, are intended to be open-ended transitional phrases, terms, or words that require the presence of the named ingredients/steps and permit the presence of other ingredients/steps. However, such description should be construed as also describing compositions or processes as “consisting of” and “consisting essentially of” the enumerated ingredients/steps, which allows the presence of only the named ingredients/steps, along with any impurities that might result therefrom, and excludes other ingredients/steps.

As used herein, the terms “about” and “at or about” mean that the amount or value in question can be the value designated some other value approximately or about the same. It is generally understood, as used herein, that it is the nominal value indicated ±10% variation unless otherwise indicated or inferred. The term is intended to convey that similar values promote equivalent results or effects recited in the claims. That is, it is understood that amounts, sizes, formulations, parameters, and other quantities and characteristics are not and need not be exact, but can be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. It is understood that where “about” is used before a quantitative value, the parameter also includes the specific quantitative value itself, unless specifically stated otherwise.

Unless indicated to the contrary, the numerical values should be understood to include numerical values which are the same when reduced to the same number of significant figures and numerical values which differ from the stated value by less than the experimental error of conventional measurement technique of the type described in the present application to determine the value.

All ranges disclosed herein are inclusive of the recited endpoint and independently of the endpoints, 2 grams and 10 grams, and all the intermediate values). The endpoints of the ranges and any values disclosed herein are not limited to the precise range or value; they are sufficiently imprecise to include values approximating these ranges and/or values.

As used herein, approximating language can be applied to modify any quantitative representation that can vary without resulting in a change in the basic function to which it is related. Accordingly, a value modified by a term or terms, such as “about” and “substantially,” may not be limited to the precise value specified, in some cases. In at least some instances, the approximating language can correspond to the precision of an instrument for measuring the value. The modifier “about” should also be considered as disclosing the range defined by the absolute values of the two endpoints. For example, the expression “from about 2 to about 4” also discloses the range “from 2 to 4.” The term “about” can refer to plus or minus 10% of the indicated number. For example, “about 10%” can indicate a range of 9% to 11%, and “about 1” can mean from 0.9-1.1. Other meanings of “about” may be apparent from the context, such as rounding off, so, for example “about 1” can also mean from 0.5 to 1.4. Further, the term “comprising” should be understood as having its open-ended meaning of “including,” but the term also includes the closed meaning of the term “consisting.” For example, a composition that comprises components A and B can be a composition that includes A, B, and other components, but can also be a composition made of A and B only. Any documents cited herein are incorporated by reference in their entireties for any and all purposes.

### Photodetectors

2D transition metal carbides, known as MXenes, are transparent when the samples are thin enough. They are also excellent electrical conductors with metal-like carrier concentrations. Herein, these characteristics are exploited to replace gold (Au) in GaAs photodetectors. By simply spin-coating transparent Ti₃C₂-based MXene electrodes from aqueous suspensions onto GaAs patterned with a photoresist and lifted off with acetone, photodetectors that outperform more standard Au electrodes are fabricated.

Both the Au and MXene-based devices show rectifying contacts with comparable Schottky barrier heights and internal electric fields. The latter, however, exhibit significantly higher responsivities and quantum efficiencies, with similar dark currents, hence showing better dynamic range and detectivity, and similar sub-nanosecond response speeds compared to the Au-based devices. The simple fabrication process is integrable into microelectronic, photonic-integrated circuits and silicon photonics processes, with a wide range of applications from optical sensing to light detection and ranging and telecommunications.

Photodetectors have a wide range of applications and are presently in great demand due to the explosion in information, data transport, and processing needs, that is facilitated by fiber optics tele/data communications. In particular, high bandwidth is essential for data center operations supporting applications such as Internet of things (IoT), autonomous vehicles, artificial intelligence, and virtual reality among other Internet demands. The need for high-speed, high-responsivity detection is traditionally met by p-type-intrinsic-n-type (PIN) photodiodes, avalanche photodiodes (APD), metal-semiconductor-metal (MSM), or metal-graphene-metal photodetectors.

Of these, top-illuminated, MSM devices are planar, relatively easy to fabricate, and are more readily integrable with field effect transistor (FET) technology as they exploit the same Schottky contacts used for the FET gate, and do not require the p and n doping of the bipolar technology. MSM photodetectors consist of two Schottky contacts typically fabricated as interdigital electrodes on top of a semiconductor. These metallic contacts—typically Ti/Pt/Au for GaAs and other III-V semiconductors—are produced by patterning a substrate by conventional photolithography, and subsequently depositing a metal under vacuum by either evaporation or sputtering, followed by either lift-off or etching. Light is absorbed between the contacts and the optically generated carriers are swept into them by an externally applied electric field that enhances the internal field of the rectifying Schottky contacts.

MSM photodetectors, however, have higher dark currents, I_{dark}, hence higher noise, compared to PINs and APDs, although several techniques exist to reduce I_{dark} by, e.g., increasing the rectifying Schottky barrier heights of the metal-semiconductor interfaces using a wider bandgap semiconductor such as AlGaAs, establishing a reduced dimensional final density of states in the semiconductor, and producing confined carrier gases which repel the injected electrons from the metal. For all these devices, high responsivity requires larger absorption areas. However, increasing a device's surface area limits its bandwidth both by increasing the RC time constants, and transit times of the optically generated carriers to the collection electrodes. A tradeoff therefore needs to be engineered depending on application.

The MXene family is one of the latest additions to the world of 2D materials. MXenes are 2D transition metal carbides or carbonitrides, discovered in 2011 and currently number around 30, with new ones discovered on a regular basis. MXenes are typically produced by selective etching the A-layers from the Mₙ₊₁AXₙ phases. The latter are layered, machinable ternary carbides and nitrides, where M is an early transition metal, A is an A-group element, and X is C and/or N and n=1 to 3. Upon etching, the A-layers, mostly Al, are replaced by various surface terminations, mostly —O, —OH, and/or —F, although recent studies show that novel terminations such as Cl can also be engineered.

### MXene Background

MXenes have shown promise in many applications such as energy storage, catalysis, EMI shielding, among many others. However, MXene oxidation in aqueous colloidal suspensions when stored in water at ambient conditions remains a challenge. Herein we show that by simply capping the edges of individual MXene flakes—herein exemplified as Ti₃C₂T_{z} and V₂CT_{z}—by polyanions such as polyphosphates, polysilicates and polyborates it is possible to quite significantly reduce their propensity for oxidation even in aerated water for weeks. This breakthrough is consistent with the realization that the edges of MXene sheets were positively charged. It is thus the first example of selectively functionalizing the edges differently from the MXene sheet surfaces.

While exemplified for these two foregoing MXene compositions, the methods employed here (and resulting compositions) extend to other MXene compositions. MXene compositions are also sometimes described in terms of the phrase “MX-enes” or “MX-ene compositions.” MXenes can be described as two-dimensional transition metal carbides, nitrides, or carbonitrides comprising at least one layer having first and second surfaces, each layer described by a formula Mₙ₊₁Xₙ Tₓ and comprising:
a substantially two-dimensional array of crystal cells,
each crystal cell having an empirical formula of Mₙ₊₁Xₙ, such that each X is positioned within an octahedral array of M,
wherein M is at least one Group IIIB, IVB, VB, or VIB metal,
wherein each X is C, N, or a combination thereof;
n=1, 2, 3, or 4; and wherein
Tₓ represents surface termination groups.

These so-called MXene compositions have been described in U.S. Pat. No. 9,193,595 and Application PCT/US2015/051588, filed Sep. 23, 2015, each of which is incorporated by reference herein in its entirety at least for its teaching of these compositions, their (electrical) properties, and their methods of making. That is, any such composition described in this Patent is considered as applicable for use in the present applications and methods and within the scope of the present invention. For the sake of completeness, M can be at least one of Sc, Y, Lu, Ti, Zr, Hf, V, Nb, Ta, Cr, Mo, or W. In certain embodiments in this class, M is at least one Group IVB, Group VB, or Group VIB metal, preferably Ti, Mo, Nb, V, or Ta. Certain of these compositions include those having one or more empirical formula wherein Mₙ₊₁Xₙ comprises Sc₂C, Ti₂C, V₂C, Cr₂C, Cr₂N, Zr₂C, Nb₂C, Hf₂C, Ti₃C₂, V₃C₂, Ta₃C₂, Ti₄C₃, V₄C₃, Ta₄C₃, Sc₂N, Ti₂N, V₂N, Cr₂N, Cr₂N, Zr₂N, Nb₂N, Hf₂C, Ti₃N₂, V₃C₂, Ta₃C₂, Ti₄N₃, V₄C₃, TaAN₃, Mo₄VC₄ or a combination or mixture thereof. In particular embodiments, the Mₙ₊₁Xₙ structure comprises Ti₃C₂, Ti₂C, Ta₄C₃ or (V_{1/2}Cr_{1/2})₃C₃. In some embodiments, M is Ti or Ta, and n is 1, 2, 3, or 4, for example having an empirical formula Ti₃C₂ or Ti₂C. In some of these embodiments, at least one of said surfaces of each layer has surface terminations comprising hydroxide, oxide, sub-oxide, or a combination thereof. In certain preferred embodiments, the MXene composition is described by a formula Mₙ₊₁XₙTₓ, where Mₙ₊₁Xₙ are Ti₂CTₓ, Mo₂TiC₂Tₓ, Ti₃C₂Tₓ, or a combination thereof, and Tₓ is as described herein. Those embodiments wherein M is Ti, and n is 1 or 2, preferably 2, are especially preferred.

In other embodiments, the articles of manufacture and methods use compositions, wherein the two-dimensional transition metal carbide, nitrides, or carbonitride comprises a composition having at least one layer having first and second surfaces, each layer comprising:
a substantially two-dimensional array of crystal cells,
each crystal cell having an empirical formula of M′₂M″ₙXₙ₊₁, such that each X is positioned within an octahedral array of M′ and M″, and where M″ₙ are present as individual two-dimensional array of atoms intercalated (sandwiched) between a pair of two-dimensional arrays of M′ atoms,
wherein M′ and M″ are different Group IIIB, IVB, VB, or VIB metals (especially where M′ and M″ are Ti, V, Nb, Ta, Cr, Mo, or a combination thereof),
wherein each X is C, N, or a combination thereof, preferably C; and n=1 or 2.

These compositions are described in, e.g., PCT/US2016/028354, filed Apr. 20, 2016, which is incorporated by reference herein in its entirety at least for its teaching of these compositions and their methods of making. For the sake of completeness, in some embodiments, M′ is Mo, and M″ is Nb, Ta, Ti, or V, or a combination thereof. In other embodiments, n is 2, M′ is Mo, Ti, V, or a combination thereof, and M″ is Cr, Nb, Ta, Ti, or V, or a combination thereof. In still further embodiments, the empirical formula M′₂M″ₙXₙ₊₁ comprises Mo₂TiC₂, Mo₂VC₂, Mo₂TaC₂, Mo₂NbC₂, Mo₂Ti₂C₃, Cr₂TiC₂, Cr₂VC₂, Cr₂TaC₂, Cr₂NbC₂, Ti₂NbC₂, Ti₂TaC₂, V₂TaC₂, or V₂TiC₂, preferably Mo₂TiC₂, Mo₂VC₂, Mo₂TaC₂, or Mo₂NbC₂, or their nitride or carbonitride analogs. In still other embodiments, M′₂M″ₙXₙ₊₁ comprises Mo₂Ti₂C₃, Mo₂V₂C₃, Mo₂Nb₂C₃, Mo₂Ta₂C₃, Cr₂Ti₂C₃, Cr₂V₂C₃, Cr₂Nb₂C₃, Cr₂Ta₂C₃, Nb₂Ta₂C₃, Ti₂Nb₂C₃, Ti₂Ta₂C₃, V₂Ta₂C₃, V₂Nb₂C₃, or V₂Ti₂C₃, preferably Mo₂Ti₂C₃, Mo₂V₂C₃, Mo₂Nb₂C₃, Mo₂Ta₂C₃, Ti₂Nb₂C₃, Ti₂Ta₂C₃, or V₂Ta₂C₃, or their nitride or carbonitride analogs.

A MXene composition can also comprise, e.g., a layer comprising a two-dimensional array of crystal cells, each crystal cell having an empirical formula of M₅X₄, such that each X is positioned within an array of M, wherein M is at least one Group IIIB, IVB, VB, or VIB metal or a lanthanide, wherein each X is C, N, or a combination thereof.

A MXene composition can also comprise, e.g., a substantially two-dimensional array of crystal cells, the layer having a first surface and a second surface, each crystal cell having an empirical formula of M₅X₄(Tₛ), such that each X is positioned within an array of M, wherein M is at least one Group IIIB, IVB, VB, or VIB metal or a lanthanide, wherein each X is C, N, or a combination thereof, wherein at least one of the first surface and the second surface comprises surface terminations Tₛ, the surface terminations independently comprising alkoxide, alkyl, carboxylate, halide, hydroxide, hydride, oxide, sub-oxide, nitride, sub-nitride, sulfonate, thiol, or any combination thereof.

Each of these compositions having empirical crystalline formulae Mₙ₊₁Xₙ or M′₂M″ₙXₙ₊₁ are described in terms of comprising at least one layer having first and second surfaces, each layer comprising a substantially two-dimensional array of crystal cells. In some embodiments, these compositions comprise layers of individual two-dimensional cells. In other embodiments, the compositions comprise a plurality of stacked layers. Additionally, in some embodiments, at least one of said surfaces of each layer has surface terminations (optionally designated “Tₛ” or “Tₓ”) comprising alkoxide, carboxylate, halide, hydroxide, hydride, oxide, sub-oxide, nitride, sub-nitride, sulfide, thiol, or a combination thereof. In some embodiments, at least one of said surfaces of each layer has surface terminations comprising alkoxide, fluoride, hydroxide, oxide, sub-oxide, or a combination thereof. In still other embodiments, both surfaces of each layer have said surface terminations comprising alkoxide, fluoride, hydroxide, oxide, sub-oxide, or a combination thereof. As used herein the terms “sub-oxide,” “sub-nitride,” or “sub-sulfide” is intended to connote a composition containing an amount reflecting a sub-stoichiometric or a mixed oxidation state of the M metal at the surface of oxide, nitride, or sulfide, respectively. For example, various forms of titania are known to exist as TiOₓ, where x can be less than 2. Accordingly, the surfaces of the present invention can also contain oxides, nitrides, or sulfides in similar sub-stoichiometric or mixed oxidation state amounts.

In the present disclosure, these MXenes can comprise simple individual layers, a plurality of stacked layers, or a combination thereof. Each layer can independently comprise surfaces functionalized by any of the surface coating features described herein (e.g., as in alkoxide, carboxylate, halide, hydroxide, hydride, oxide, sub-oxide, nitride, sub-nitride, sulfide, thiol, or a combination thereof) or can be also partially or completely functionalized by polymers, either on the surface of individual layers, for example, where the two-dimensional compositions are embedded within a polymer matrix, or the polymers can be intercalated between layers to form structural composites, or both.

Interest in MXenes has exploded recently for a number of reasons, chief among them is that they are hydrophilic and yet quite conductive. Another reason is the ease by which large quantities of stable aqueous colloidal suspensions are produced. A number of excellent review articles exist on these materials. To date, MXenes have been used in numerous applications, achieving, in many cases, record values. MXenes have been used as electrodes in batteries and electrochemical capacitors, textile supercapacitors, photodetectors, electrical contacts such as Schottky electrodes, or ohmic contacts with modified MXene chemistries, and spayed-on antennas. Because transparent contacts are widely used for touch sensitive screens, solar cells, and organic light emitting diodes (OLED), MXenes can be used for these applications.

Using MXene transparent contacts offers an obvious advantage that mitigates the aforementioned tradeoff between carrier transit distance and responsivity, should they maintain, as shown below, other important attributes of Schottky metal-semiconductor contacts such as large barrier heights, built-in potentials, and large internal electric fields. As noted, if thin enough, MXene films are both conductive and transparent. Here, we deposit transparent, metallic Ti₃C₂T_{z}-based contacts on gallium arsenide (GaAs), substrates to produce MXene-semiconducting-MXene, henceforth referred to as MX-S-MX, photodetecting devices. The purpose of this work is to quantify the optoelectronic characteristics of MX-S-MX devices and compare them to conventional MSM devices with Ti/Au Schottky contacts. In what follows, we produce thin MXene films and characterize their optical properties. In order to construct a device, however, it is necessary to pattern the electrodes. MXene patterning has previously been carried out using laser printers, or microcontact printing techniques. The resulting feature sizes—in the hundreds of micrometers range—are too large for our purpose. Microintaglio printing has been used for patterning other types of 2D materials, carried out in vacuum chambers. Here, we show that much finer patterning, limited by our photolithography, is possible, where the MXene films are spin-coated on GaAs substrates and lifted off by simple immersion in acetone. Schematics of the fabrication processes and resulting devices together with energy band diagrams are shown in FIGa. 1A-1I.

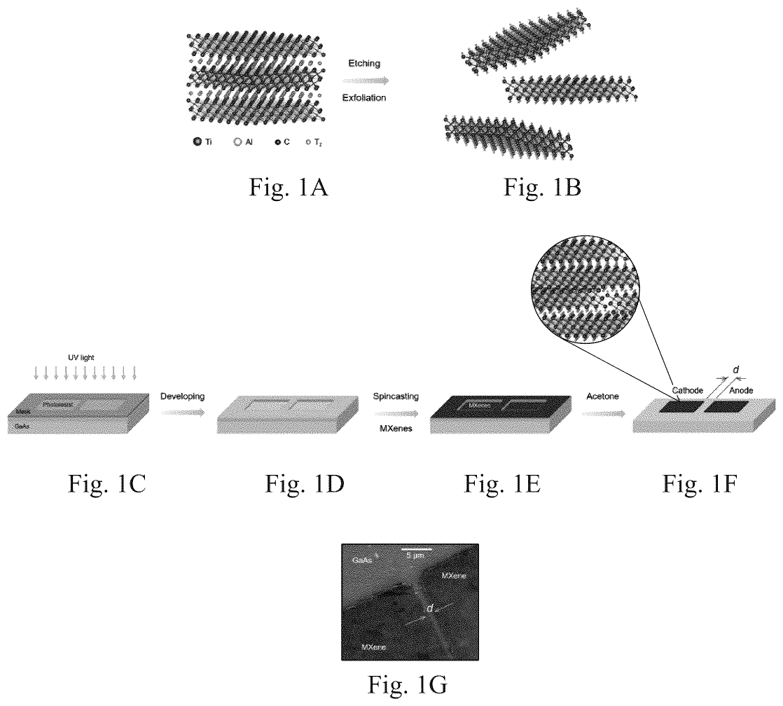

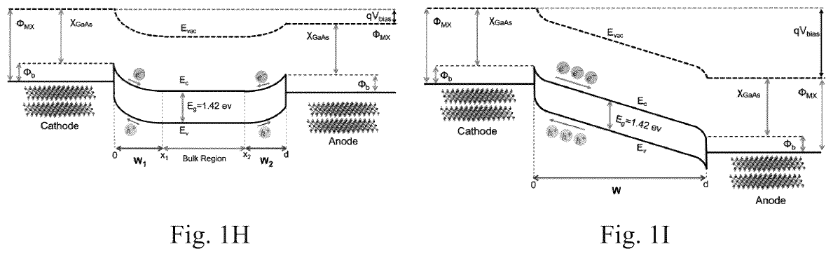

The process used, shown schematically in FIGS. 1A-1I, is carried out at room temperature in ambient air, and resulted in device feature sizes of the order of 2 μm, although the devices studied here have larger separations between contacts. The results reported below confirm that this inexpensive, simple, scalable process results in photodetectors that were as good as and, in most attributes, better than those fabricated with Ti/Au electrodes.

The MXene chosen for this work is Ti₃C₂T_{z} because it is the most studied. It should be understood, however, that Ti₃C₂T_{z} is used herein as an example only, and that the present disclosure is not limited to Ti₃C₂T_{z} MXenes.

To make our devices, first the Ti₃AlC₂ MAX phase (FIG. 1A) was etched and delaminated (FIG. 1B). The electrode pattern was then formed using photoresist and contact lithography on the GaAs substrate (FIG. 1C) and developed (FIG. 1D). The MXene colloidal suspension was then spin cast on the substrate (FIG. 1E). Lastly, the photoresist was removed by immersing the device in acetone (FIG. 1F) leaving two MXene pads. Spacings as narrow as 2 μm were obtained. The sharpness of the edges and corners is noteworthy, indicating that the resolution of this method is limited by lithography; our results are orders of magnitude better than prior work. Details of the fabrication methods and experimental techniques can be found elsewhere herein. The energy band diagram of our MX-S-MX device is shown in FIG. 1H under moderate bias, and under large external bias in FIG. 1I[[i]].

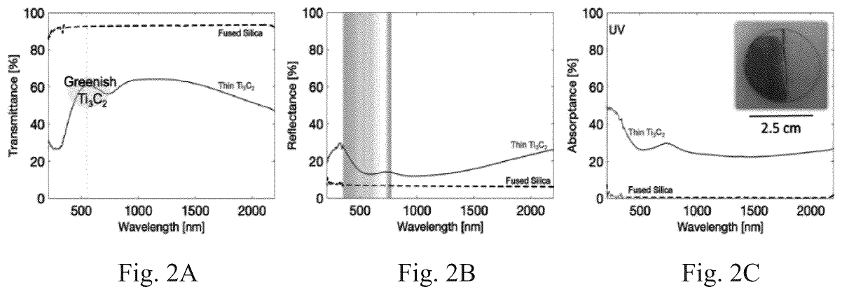

Before photodetector device fabrication, a thin Ti₃C₂T_{z} film was deposited on a silica substrate. FIGS. 2A-2C show the measured transmittance and reflectance of a Ti₃C₂T_{z} film of thickness ˜19.2 nm, indicated as “thin,” which was used for device fabrication. The absorptance spectrum, absorptance=1 (reflectance+transmittance), is calculated in FIG. 2C, the inset of which shows that half of the silica samples were covered and provide the baseline spectra that is shown in these figures. The wide absorption spectra, from 350 to 2200 nm, of these films are notable, with the interesting attribute of high absorptance in the UV range.

FIG. 1G shows typical scanning electron microscopy (SEM) images of two Ti₃C₂-based pads separated by a gap of ≈2 μm. The results reported below confirmed that this inexpensive, simple, scalable process resulted in photodetectors that were as good as and, in most figures of merit (FOM), better than those fabricated with Ti/Au electrodes. This is notable given that—apart from the mask aligner—nothing more sophisticated than a tabletop spin-coater was needed. This ambient condition process can be readily integrated into microelectronic, photonic-integrated circuit (PIC), and silicon photonics (SiP) processes, with a wide spectrum of possible applications ranging from optical sensing to light detection and ranging (LiDAR), to optical tele/data communications.

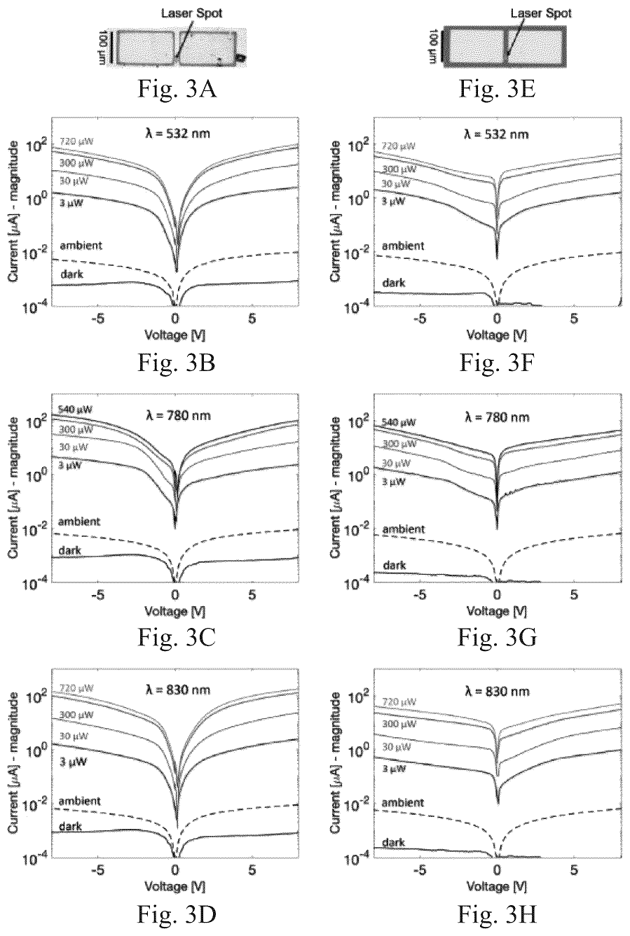

To allow for side-by-side comparisons, Ti/Au—GaAs—Ti/Au MSM devices were fabricated using the same mask set and lithography technique as for the MX-based devices. In this case, electron-gun evaporation of, first a 5 nm Ti adhesion layer, followed by a 120 nm Au layer was used to deposit the electrodes. Pictures of the two devices are shown side by side in FIG. 3A and FIG. 3E. FIGS. 3A-3H compare the current-voltage (I-V) optical response of identical geometry devices—one MXene (left-hand column) and the other Au-based (right-hand column)—under dark and at wavelengths of 532, 780, and 830 nm as a function of bias. The λ of 532 and 780 nm were used to stress contact transparency; the 830 nm because it is used for high-speed, short-range optical tele/data communications applications.

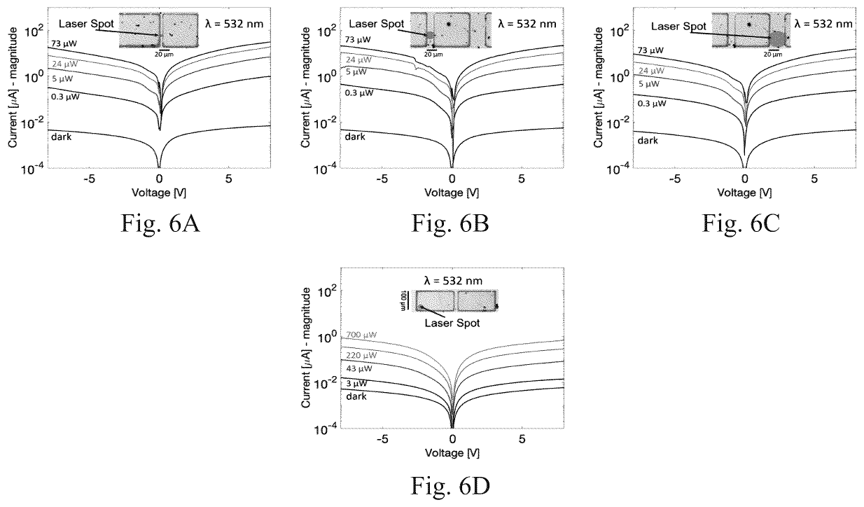

FIGS. 3A-3H show that the MXene-based device has a dark current, I_{dark} of 0.6 nA at (533 nm) and 0.9 nA at (780 and 830 nm) for MX, which is comparable to 0.2 nA for Ti/Au MSM, and is remarkably low for such a large area device. In order to investigate the mechanisms of I_{dark} flow across the MXene-semiconductor junction devices with cathode-anode gaps of 5, 15, and 35 μm, respectively, were fabricated. I_{dark} is independent of gap size, and relatively independent of the applied voltage. Had the contacts been ohmic, the current would have changed by a factor of 3 and 7, respectively, relative to the 5 μm gap of the device shown in FIG. 6A. This means that a rectifying Schottky barrier exists at the MX-S interface, which dominates current transport. It follows that the energy band diagrams depicted in FIG. 1H and FIG. 1I are applicable. This also implies band bending and the presence of an internal electric field at the contacts, which in turn affects the transport and collection of the optically generated carriers.

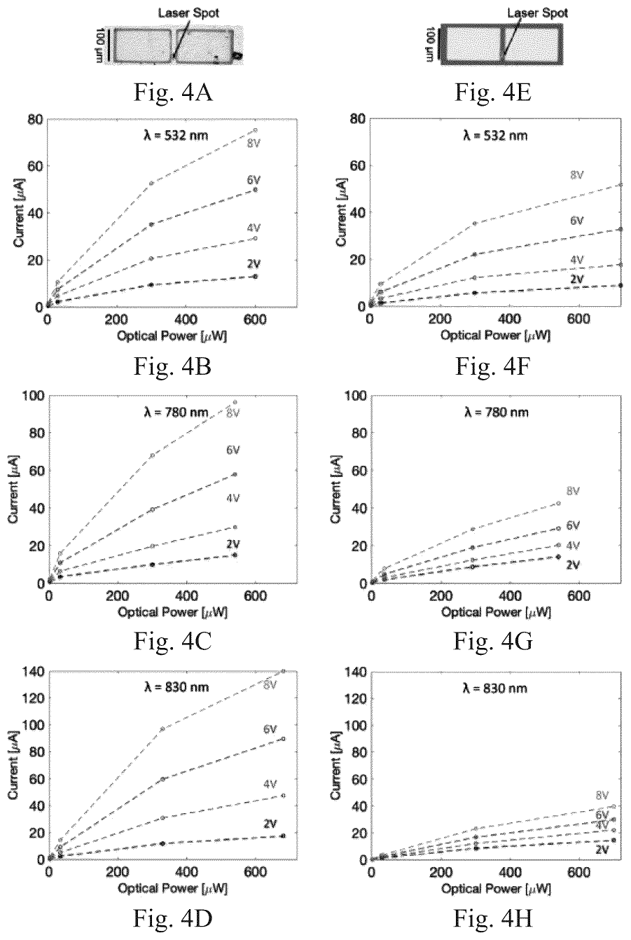

Besides having similar I_{dark}, hence noise, a remarkable five orders of magnitude change in photocurrent is observed at 8 V bias under illumination by 0.34 μW of optical power. A comparison of the photocurrent versus optical power is shown in FIGS. 4A-4H for λ=532, 780, and 830 nm, at various biases. It is clearly observed that replacing Au with MXene substantially improves the optical response, particularly for λ=830 nm where an enhancement by a factor of nearly 4 is observed at 8 V bias.

Responsivity, defined as the ratio of photocurrent to incident optical power

$$R = \frac{{I}_{ph}}{{P}_{opt}} [ mA {W}^{- 1} ]$$

can be extracted. The results are listed in Table 1 below.

External quantum efficiency (QE), η is defined as the number of electrons circulating in the external circuitry per incident photon, and relates to responsivity by:

$$η = \frac{1.24 \times R}{λ} ( λ in μm ) .$$

That data is consistent with FIGS. 4A-4I and Table 1. It shows that replacing Au by MXene in these devices substantially increases their responsivity and quantum efficiency for all wavelengths and at all bias levels. In fact, the 280 mA W⁻¹ responsivity observed under 8 V bias at 830 nm meets the stringent needs of LiDAR applications, is quite remarkable for this simple device and is better than the Ti/Au-device responsivity of ≈72 mA W⁻¹ (see Table 1).

Responsivity (R), relates to detectivity,

$${D}^{*} = R / \sqrt{\frac{2 q}{A} {I}_{d a r k}} ,$$

and allows us to determine an important figure of merit, the noise equivalent power (NEP), which determines the minimum incident power, where the detector can distinguish a signal from the background noise level. NEP can be approximated as NEP=\sqrt{A*Δf}/D^{*}, where Δf is the measurement bandwidth and A is the active area of the device taken to be the area of the laser spot in both cases.

Table 2 provides a comparison of the MXene-and Ti/Au-based devices on the basis of several FOMs, namely, R [mA W⁻¹], QE, D* [Jones],

$$NEP [ \frac{W}{\sqrt{Hz}} ] ,$$

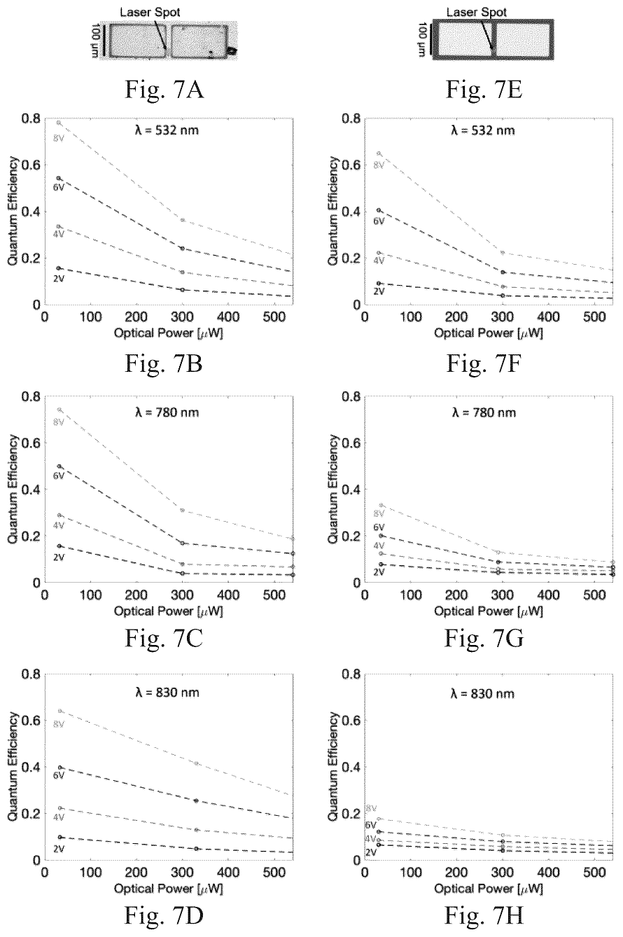

and dynamic range (DR) [dB] defined as

$$10 {log}_{10} \frac{{P}_{i n}}{NEP} ,$$

where Pᵢₙ is optical input power. Further insight into the large DR is provided in FIGS. 4A-4H[[I]] which shows photocurrent versus incident optical power at three wavelengths and several bias conditions, as well as FIGS. 7A-7H, which compare the external quantum efficiency of Au- and MXene-based devices at these wavelengths. On the basis of all these FOMs, the MXene-based device that is simply spun on a wafer and dipped in acetone, outperforms Ti/Au by a large margin, the most impressive of which, perhaps, is achieving nearly four times improvement in R at the desirable wavelength of 830 nm (Table 1). Considering these FOMs, the MX-S-MX devices have enhanced performance metrics compared to a number of 2D-based photodetector technologies currently in use.

TABLE 1
Responsivity [mA W⁻¹] at ≈300 μW input power

| Bias | MXene-GaAs-MXene | | | Ti/Au MSM | | |
|---|---|---|---|---|---|---|
| [V] | 532 nm | 780 nm | 830 nm | 532 nm | 780 nm | 830 nm |
| 2 | 27 | 24 | 32 | 16 | 26 | 27 |
| 4 | 59 | 50 | 86 | 33 | 36 | 38 |
| 6 | 103 | 106 | 170 | 59 | 55 | 53 |
| 8 | 155 | 195 | 278 | 95 | 82 | 72 |

To emphasize the importance of electrode contact transparency, we illuminated a corner of our MXene-based device as shown in FIG. 6D. A change in photocurrent by a factor of ≈400 was obtained due to the transparency of the contacts, and does not have a counterpart in the Ti/Au MSM device. This provides a promising platform in cases where the light source is highly divergent, and is difficult to focus all the light power on an active region with narrow feature sizes. The transparency of the contacts as well as their increase in conductivity under illumination are potentially useful in applications such as neuronal recording, particularly for optogenetics purposes.

TABLE 2
Figures of merit (FOM) at = 300 μW input power, under 8 V bias.

| | | Figures of merit | | | | |
|---|---|---|---|---|---|---|
| Photo- detector | λ [nm] | R [mA W⁻¹] | η [%] | D* [Jones] | $NEP [ \frac{W}{\sqrt{Hz}} ]$ | DR [dB] |
| MX-5-MX | 532 | 155 | 36 | 8 × 10¹⁰ | 6.3 × 10⁻¹⁴ | 96.7 |
| | 780 | 195 | 31 | 8.1 × 10¹⁰ | 6.1 × 10⁻¹⁴ | 96.9 |
| | 830 | 278 | 42 | 11.6 × 10¹⁰ | 4.3 × 10⁻¹⁴ | 98.4 |
| Ti/Au MSM | 532 | 95 | 22 | 7.9 × 10¹⁰ | 6.2 × 10⁻¹⁴ | 96.8 |
| | 780 | 82 | 13 | 7.2 × 10¹⁰ | 6.9 × 10⁻¹⁴ | 96.3 |
| | 830 | 72 | 11 | 6.3 × 10¹⁰ | 7.9 × 10⁻¹⁴ | 95.7 |

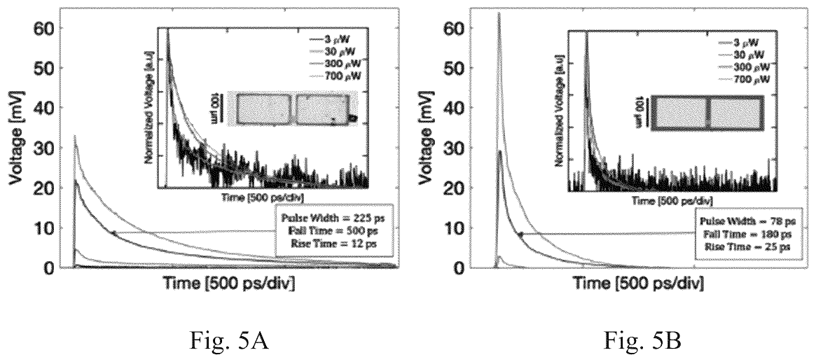

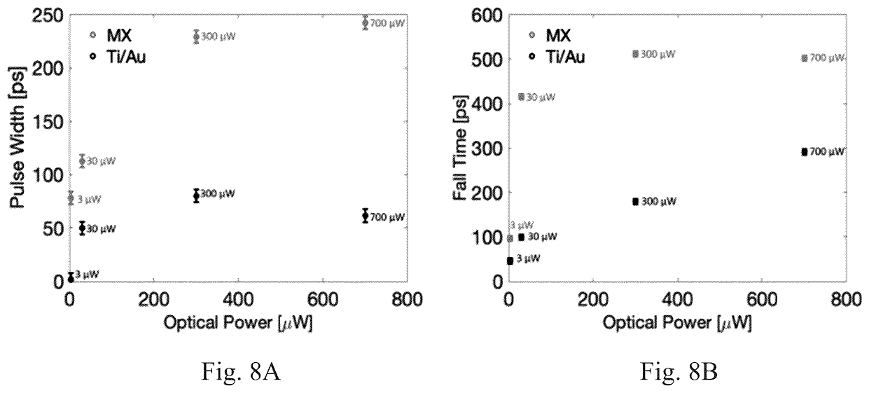

The devices' optoelectronic response was measured at four average optical powers (3, 30, 300, and 700 μW) with 8 V of bias applied through a bias-T. FIG. 5A shows the MXene-based device's response, while FIG. 5B is the pulse response of the Ti/Au device, which compare temporal responses at 300 μW optical power. Measured fall time and pulse width values are given in FIGS. 5A-5B and reported for other optical powers in FIGS. 8A-8B. Our MXene-based device exhibits a fast pulse width of 225 ps, which, although slower than Ti/Au's 78 ps, still corresponds to operation near the 3 GHz range, which meets many of present speed requirements and is orders of magnitude better than competing previous works in perovskite/MXene devices that reported an 18 ms time response. Considering the large cathode-anode transit distance in present devices, optimization of device geometry should result in faster MXene-based devices.

As experimentally shown above, the MXene-GaAs contacts are rectifying (Schottky), hence I_{dark} of the MX-S-MX device is dominated by the properties of the reverse biased cathode, described by the Richardson and Dushman equation

$${I}_{d a r k} = A * {T}^{2} A exp ( \frac{- q {ϕ}_{B}}{{K}_{B} T} ) exp ( \frac{q Δ {ϕ}_{i m}}{{K}_{B} T} ) \qquad ( 1 )$$

where ϕ_{B} is the Schottky barrier height, A* is the Richardson constant, ϕᵢₘ is the barrier lowering due to the image force, and other symbols have their usual meaning. Equation (1) shows the significance of the Schottky barrier height in determining the I_{dark} values. In the limiting case, that the semiconductor has no surface states, the barrier height is the difference of the metal work function (ϕₘ) and semiconductor electron affinity (χₛ): ϕ_{B}=ϕₘ−χₛ. This only applies to silicon, however. In our case, due to the large number of surface states, the Fermi level is pinned at the semiconductor, resulting in barrier heights that are relatively independent of ϕₘ, and for III-V compounds, such as GaAs, is

$${ϕ}_{B} \approx \frac{2}{3} {E}_{g} = 0.8 eV .$$

The fact that I_{dark} in FIG. 3A-3H is comparable for the MXene and Au-based devices, and that it is independent of the cathode-anode distance, validates the point that our Ti₃C₂-based electrodes act like any other metal on GaAs. It is thus not surprising that it can substitute for Au, with the advantage of being formed at room temperature, using tabletop equipment, with no need for vacuum deposition, at low cost, while also being transparent to light.

The MX-S-MX device is thus similar to an MSMs and consists of two back-to-back Schottky diodes, with a barrier between MXene and semiconductor, the value of which is primarily determined by the pinned Fermi level on the GaAs side. This contact produces a built-in voltage, a strong local electric field on the GaAs side, and a concomitant depletion region, the width of which depends on the built-in voltage. Application of a bias voltage, causes one of the contacts to become a reverse biased cathode, which dominates current transport.

FIG. 1H shows a sketch of the energy band diagram (EBD) of the MX-S-MX device under moderate applied external bias, most of which is dropped at the cathode, extending its depletion region (W₁) to point x₁, with the remainder dropping at the anode and reducing its depletion width (W₂) to point x₂. While W₁ and W₂ are under strong (>10 kV cm⁻¹) e-fields, the remainder of the distance between contacts, namely, (x₂−x₁), is undepleted bulk with no e-field, and is in the so-called below “reach-through” condition. Further increase of bias depletes the whole distance (W), between contacts and is called “flat-band” as shown in FIG. 1I.

FIGS. 1H and 1I help elucidate device behavior when light illuminates the gap between the contacts. Several current components can be observed, including the holes that are generated within W₁ and are swept quickly to the cathode. The electrons, on the other hand, drift to the edge of the depletion region, where they would diffuse through the bulk, overcome the built-in voltage at the anode, and are collected there. The electron-hole pairs (EHP) generated in the anode region W₂, have an opposite flux, however, their numbers are much smaller since W₁>>W₂.

By neglecting carriers recombination, and applying the condition of continuity of current in both depletion regions, the total current of the photodetector is calculated.

For a special case in which the undepleted region is much wider than the diffusion length, and W₁>>W₂, a descriptive equation reduces to

$$J = qG ( {W}_{1} + {L}_{p} ) \qquad ( 2 )$$

which means that EHPs generated within W₁, and those within a hole diffusion length of it, constitute the majority of the photocurrent. Hence, while contact separation W varies from 5 to 15 to 35 μm, as shown in FIGS. 6A-6D, the cathode depletion width W₁ remains unchanged and depends only on applied bias. As a result, the photocurrents are comparable for these devices, depending only on the applied bias. In the other extreme, the flat-band condition shown in FIG. 1I is reached if W is small, and the photocurrent simply saturates at J=qGW.

Examining the temporal response, holes generated within W₁ are swept quickly by the electric field and collected at the cathode, while electrons generated within the same region need to traverse the whole gap. Under constant illumination, both carriers are collected in MXene-based devices and, added to the fact that contacts are transparent, result in higher responsivity. In transient response, however, Ti/Au has a stronger built-in field in a larger W₁ which is presumably why they show faster speeds and more efficient carrier collection. It is acknowledged that these considerations based on the analysis outlined above are only qualitative and need further study to elucidate the reasons for the very high responsivity, and comparable speed, of the MXene-based devices. Also, operating beyond reach-through is an optimized condition for device design since it eliminates slow diffusion processes, and is possible to achieve with small feature sizes our fabrication technique allows.

Herein, we show that using a cheap and simple three-step process based on photolithography, spin-coating, and lift-off, transparent MXene contacts with feature sizes limited by lithography can be produced. The resulting contacts are Schottky, which resulted in MXene-GaAs-MXene photodetector devices that outperformed in terms of responsivity, quantum efficiency and dynamic range similar Ti/Au—GaAs—Ti/Au devices. They were also comparable in speed of response, and, at a pulse width of a fraction of a nanosecond, could operate in a few gigahertzs range, meeting stringent requirements of optical detection for tele/data communications. All these performance measures can be improved by device optimization which our fabrication process affords. Due to the scalability of this process, microfabrication of devices can be done for photonic integrated circuit and silicon photonics technologies. Additionally, as Schottky contact, MXene is a strong candidate for use as (transparent) gate of metal-semiconductor field effect transistors (MESFETs), and high electron mobility transistors (HEMTs) which are the dominant devices in high-speed high-power applications.

Finally, MXenes, including Ti₃C₂T_{z} used here, have the unique attribute that their work function can be adjusted from 2.14 to 5.65 eV by different means, such as hole injection or surface termination using oxygen, fluorine, or chlorine. This provides a wider range compared to all metals used in MSM detectors. Consequently, if the Fermi level is not pinned in the semiconductor, as is the case in silicon, MXenes could be used as ohmic, or Schottky contacts at will, resulting in a range of optoelectronic applications, such as having low noise MSMs with Schottky contacts, or high gain photoconductors with two ohmic contacts. Furthermore, the idea that ohmic contacts can be formed by proper surface termination of MXene, is quite appealing to the microelectronic industry.

It should also be mentioned that stability and durability of MXenes remain as important challenges. One promising recent remedy to MXene oxidation in aqueous colloidal suspensions when stored in water at ambient conditions is to simply cap the edges of individual MXene flakes by polyanions such as polyphosphates, polysilicates, and polyborates. This selective functionalization of the edges differently from the surfaces has been shown to significantly reduce their propensity for oxidation even in aerated water for weeks.

### Experimental

Current-voltage (I-V) relations were measured at wavelengths of 532, 780, and 830 nm as a function of bias. The biasing voltage was swept from ±8 V, in order to detect for any hysteresis effects. The incident light power was varied from dark to 3, 43, 220, and 700 μW, and then back to dark for all experiments. The photodetector response measurements used a 532 nm continuous wave laser and a 780 and 830 nm mode-locked laser operating at a repetition rate of 76 MHz. In all cases, the laser spot was focused with a 20× microscope objective onto the sample and subsequently expanded to the gap between electrodes. Electrical contact with the pads was made using 60+GHz microwave probes (Picoprobe model 67 A). The bias voltage and current measurements were made through a bias-T using a source meter (Keithley 2400).

### Additional Photodetector Disclosure

### Preparation of MXenes Colloidal Suspension

In order to examine the optical properties of MXene, a film of Ti₃C₂T_{z} was obtained by spin-casting the suspension (30 s at 800 rpm and 10 s at 2000 rpm) onto a silica substrate. The film thickness was measured optically and is controllable by the rotation speed. The sample was annealed under dynamic vacuum for 12 h under a 100° C. heater. Silica substrate was cleaned under sonication in alkaline detergent with half of the substrate being covered with parafilm so as to have an uncoated area in order to acquire an accurate baseline for optical measurement. This can result in a film that is less homogeneous than the one typically obtained with spin-casting; however, the active device area that is subsequently produced is homogeneous as verified by SEM measurements.

Ti₃AlC₂, (Ti₃C₂T_{z} precursor) was synthesized by heating a ball-mixed mixture of TiC, Al and Ti (Alfa Aesar, 99.5% purity) powders in a molar ratio of 2:1.05:1, respectively, under flowing argon (Ar) at a rate of 5° C./min to 1350° C. and holding time of 2 h. The resulting solid is milled and sieved (-400 mesh) to obtain a powder with particle size of less than 38 um.

The Ti₃AlC₂ MAX powders were used for preparing the colloidal suspension of MXene. One gram of lithium fluoride (LiF) was dissolved in 10 mL of 12 M hydrochloric acid, followed by the slow addition of the powders. The solution was stirred at 35° C. for 24 h. The powder was then washed seven times with distilled water in a centrifugation and decantation process (3500 rpm, 2 min) until the supernatant reached a pH of ≈5 and spontaneous delamination was observed. 20 mL of distilled water was then added to the sediment and the mixture was sonicated for 1 h at room temperature under bubbling Ar, and subsequently centrifuged at 3500 rpm for 1 h. The supernatant collected contained mostly single Ti₃C₂T_{z} flakes. The concentration of flakes in the solution was determined by vacuum filtering of a given volume solution, drying the resulting film at 100° C. for 12 h under dynamic vacuum and weighting it.

Before deposition of the MXene flakes, the SiO2 silica substrates were cleaned using sonication in alkaline detergent (1 time, 5 min), water (3 times, 1 min) and then ethanol (3 times, 1 min). A film of Ti₃C₂T_{z} was spincasted using colloidal solutions of single flakes with Ti₃C₂ solution concentration of 6.4 g/L.

The thickness of the spin-casted film of Ti₃C₂T_{z} on silica is estimated using the following linear equation and the measured transmission percentage of the film at 550 nm: A=0.0114t+0.0352 where t is the thickness in nanometers and A is −log10(Transmission). Therefore, the thickness of the sample is estimated to be 19.2 nm. Transmitted spectrum of the sample compared to the silica baseline was measured using a Cary UMA spectrophotometer.

### Photolithography and Device Fabrication

Silica and semi-insulating GaAs wafers were cleaned by spraying acetone, methanol, and isopropanol, then dried with a nitrogen gun. Microposit S1813 photoresist was spun on the substrates (at 2000 rpm for 60 s), producing a ≈2 μm thick coating, and baked on a hot-plate at 115° C. for 60 s. Positive photolithography was performed on samples by UV exposure at 290 J·cm⁻² for 6 seconds using a contact mask aligner, followed by chemical development in Microposit MF CD-26 developer for 60 s, rinsed, and dried. Films of Ti₃C₂T_{z} were spincasted on a semi-insulating GaAs substrate at 800 rpm for 30 s, using a colloidal suspension of single flakes with a solid concentration of 5.7 g·L⁻¹. Photo resist was removed by immersing the sample in acetone for 10 s, leaving patterned MXene on the substrate. The die was dried at 100° C. for 12 h under dynamic vacuum. Photolithography details are described in Table 3.

SEM inspection of the patterned films, shows that relatively homogeneous MXene films with smooth edges and sharp corners are produced using this straight-forward process based on spin-casting, conventional lithography, and wet chemical processing. Given the morphology of spincast of MXene flakes, we expect that these films can be patterned to the same level of resolution and same feature sizes as other photolitographically defined lift-off processes for metals that have reached deep sub-micron levels.

### MX-S-MX Photodetector Properties

To characterize the contact properties of MXene-Semiconductor (MX-S) junctions, we measured I-V characteristics as a function of the gap size (d), between electrodes. Here, dark currents, I_{dark}, of the order of few nanoamps are measured; notably the dark current is independent of the gap size. Had the current been based on GaAs conductivity, it would change by a factor of 3 and 7 for gap sizes of 15 μm (FIG. 1B), and 35 μm (FIG. 6C), respectively, when compared to that of d=5 μm (FIG. 6A).

TABLE 3
Process flow for fabrication of MX-S-MX photodetector on GaAs
using wet chemistry photolithography.
Wet Chemistry Lithography

| | | |
|---|---|---|
| Lithography | Resist type | S1813 |
| on GaAs | Resist Thickness | 2.18 μm |
| | Bake Temperature and Time | 115° C. and 60 s |
| | Exposure Time and Power | 6 s and 290 J/cm² |
| | Developer Type | Microposit MF CD-26 |
| | Development Time | Developer |
| | | 120 s |
| Mxene | MXene Type | Ti₃C₂ |
| Deposition | Spinner rpm and Time | 800 rpm and 30 s |
| | MXene Concentration | 5.7 g · L⁻¹ |
| | Annealing Pressure and Time | Dynamic Vacuum for 12 h |
| | Annealing Temperature | 100° C. |
| Lift-off | Immersion in Acetone | 10 s |
| | Drying | Nitrogen Gun |

Transparency of MXene adds an important obvious advantage to gold electrodes. FIG. 1D shows I-V of a device, where the laser spot illuminates a far corner of one of the MXene contact electrodes.

### Quantum Efficiency of the MX-S-MX Detector Versus the Ti/Au MSM

FIGS. 7A-7H compare quantum efficiencies, n, of the MX-S-MX and Ti/Au MSM devices at λ=532 and 780 and 830 nm under 2 to 8 V biasing voltages. Importantly, the MX-S-MX photodetectors exhibit QEs that are generally 1.5-3 times greater than those of Ti/Au MSM counterparts. Notably, the MXene film production and deposition costs are much less than acquirement and processing of precious metals (Au, Ti, Pt, etc.) commonly used for device fabrication.

Table 4 summarizes the quantum efficiency of the MX-S-MX device, compared to that of the Ti/Au MSM detector at a 300 μW power of incident coherent illumination.

TABLE 4
Quantum Efficiency [%] at ≈300 μW Input Power

| Bias | MXene-GaAs-MXene | | | Ti/Au MSM | | |
|---|---|---|---|---|---|---|
| (V) | 532 nm | 780 nm | 830 nm | 532 nm | 780 nm | 830 nm |
| 2 | 6 | 4 | 5 | 4 | 4 | 4 |
| 4 | 14 | 8 | 13 | 8 | 6 | 6 |
| 6 | 24 | 17 | 25 | 14 | 9 | 8 |
| 8 | 36 | 31 | 42 | 22 | 13 | 11 |

### Temporal Response Characteristics of the MX-S-MX Detector Versus Ti/Au MSM

The time response of these photodetectors were measured using an optoelectronic sampling method with an illumination of 100 fs pulses from a Ti: sapphire laser, operating at a 830 nm center wavelength and a 76 MHz repetition rate. Fall time and pulse width values are reported for various optical powers in FIGS. 8A-8B for a MX-S-MX detector (FIG. 8A) and a Ti/Au MSM device (FIG. 8B). Error bars indicate the resolution of the measurement technique.

Measurement results shown in FIGS. 8A-8B, shows that the Ti/Au device is faster, having a shorter pulse width and fall time, compared to those for the MXene device; both devices, however, are transit time limited and are quite fast given the large size of the contact pads and relatively large separations (>5 μm) between them.

### Modeling of MX-S-MX Operations Under Zero, Moderate, and High Bias Conditions

### Modes of Operation Based on the Energy Band Diagram

Three distinct regions of operation can be identified for the MX-S-MX device with contact spacing of d. Similar to that of metal-semiconductor junctions, depletion regions with widths of W₁ and W₂ are established at the cathode and the anode, respectively:
1. Zero applied bias: The flat band between the contacts is at its maximum extents, bounded by the equilibrium depletion regions on both the anode and the cathode sides, each with depletion width of Wd.
2. Moderate bias: An applied (positive) voltage causes an extension of the cathode depletion region, however, some flat-band condition still exists between the anode and cathode (W₁+W₂<d). This is also known as a pre-punch through bias condition;
3. High bias region: The applied voltage is large enough to force the depletion region under cathode reach through that of the anode cathode (W₁+W₂=d). No flat-band exists in this case.

At zero bias condition, W_{d} is related to the MXene-GaAs junction built-in potential, Obi, and the impurity concentration of the semiconductor, Nₐ, similar to that of a Schottky diode as:

$${W}_{d} = \sqrt{\frac{2 ∈ ( {ϕ}_{bi} {V}_{a} )}{q {N}_{a}}} \qquad ( S1 )$$

where Vₐ, is the applied biasing voltage and is 0 V for the case of equilibrium. The built-in potential can be calculated using Eq. (S2):

$${ϕ}_{b i} = {ϕ}_{b} - {V}_{t} ln ( \frac{{N}_{v}}{{N}_{a}} ) , \qquad ( S2 )$$

where ϕ_{b} is the barrier height at MXene-GaAs interface, Nᵥ is the effective density of states in GaAs valence band, and Nₐ is the impurity concentration at the substrate. As-grown semi-insulating GaAs wafers are generally unintentionally p-doped with concentrations of N₂≈10¹⁴ cm⁻³. Furthermore, Fermi level pinning because of the surface states of GaAs results in a fixed barrier height ϕ_{b}=0.8 eV, leads to the built-in potential ϕ_{bi}=0.51 eV-calculated from Eq. (S2)—for our device-under-test (DUT). Finally, the equilibrium depletion width of W_{d}=2.7 μm is calculated using Eqs. (S1) and (S2).

### Current Flow in MX-S-MX Photodetector

The overall (dark or photo) current density, Jₜₒₜ, in MX-S-MX photodetector is the sum of current components at cathode, Jₒ₊, and anode J_{d-} as:

$$J = {J}_{0 +} + {J}_{d -} \qquad ( S3 )$$

Additionally, drift and diffusion of carriers in depletion and flat-band regions, respectively, contribute to the total current. Here we first analyze the general case of a moderate bias condition and then apply it to zero- and high-bias conditions.

Under a uniform optical excitation with a carrier generation rate of G and neglecting the recombination of carriers, the electric charge continuity equation is stated as:

$$- \frac{1}{q} \frac{\partial J 9 x )}{\partial x} + G = 0 \qquad ( S4 )$$

where q is the unit of charge and J(x) is the current density at a distance x away from the cathode. At the edges of the depletion regions on the cathode and the anode, denoted by x₁ and x₂, respectively, the current density at each electrode can be expressed as the sum of the drift and the diffusion of carriers as:

$${J}_{0 +} = {J}_{x 1} - q G {W}_{1} \qquad ( S5 )$$

$${J}_{d} = {J}_{x 2} + q G {W}_{2} \qquad ( S6 )$$

Jₓ₁ and Jₓ₂ can be found from solving for the diffusion of the excess minority carriers, δp(x), at the flat-band regions in steady state:

$${D}_{p} \frac{{d}^{2} δ p ( x )}{d {x}^{2}} - \frac{δ p ( x )}{{τ}_{p ( x )}} + G = 0 \qquad ( S7 )$$

where Dₚ is the diffusion coefficient, τₚ is the lifetime, and δp is the excess hole concentration. By neglecting the hole concentration at the edge of the depletion region near cathode, Eq. (S7) simplifies to:

$$δ p ( x ) = A exp ( x / {L}_{p} ) + B exp ( - x / {L}_{p} ) + \frac{{L}_{p}^{2}}{{D}_{p}} G \qquad ( S8 )$$

which by application of boundary condition, the current at the edge of the cathode becomes:

$${J}_{x 1} = - q G {L}_{p} ( tanh ( \frac{{x}_{2} - {x}_{a}}{{L}_{p}} ) - \frac{1}{{L}_{p}} sech ( \frac{{x}_{2} - {x}_{1}}{{L}_{p}} ) ) \qquad ( S9 )$$

where Lₚ=\sqrt{Dₚ·τₚ} is the diffusion length for holes.

On the anode side (x =x₂):

$$q {D}_{p} \frac{\partial δ p ( x )}{\partial x} + q G f = 0 \qquad ( S10 )$$

where f is the effective diffusion length at the anode. The anode's current density is based on the diffusion process, where f parameter fits the physical expectations to the measurement results. Jₓ₂ is calculated as follows:

$${J}_{x 2} = q G f \qquad ( S11 )$$

The total current for MX-S-MX device now can be expressed by replacing Eqs. (S9) and (S11) into Eq. (S3) as:

$$J = q G ( {W}_{1} - {W}_{2} ) - q G {L}_{p} tanh ( \frac{{x}_{2} - {x}_{1}}{{L}_{p}} ) + qGf sech ( \frac{{x}_{2} - {x}_{1}}{{L}_{p}} ) + qGf \qquad ( S12 )$$

The gap (d) between the two electrodes in the MX-S-MX detector, determines the role of diffusion of carriers in the device. For our device-under-test (DUT), the length of the flat-band region is much larger than the diffusion length, that is x₂−x₁>>Lₚ. Therefore the total current of the detector can be summarized as:

$$J = - q G ( {W}_{1} - {W}_{2} ) + q G ( {L}_{p} - f ) \qquad ( S13 )$$

where the term −qG(W₁−W₂) represents drift current at the anode and the cathode depletion regions, while the second term +qG(Lₚ−f) accounts for the diffusion of holes within an average distance f from the edges of both depletion regions.

The case of the equilibrium/close-to-zero applied bias voltage can be viewed as a special case for pre-reach-through, in which x₁=x₂=xₐ, therefore the effective diffusion length, f, at the anode is equal the diffusion length, Lₚ; the total current then becomes:

$$J = - q G ( {W}_{1} - {W}_{2} ) \qquad ( S14 )$$

Since at zero bias and because of the symmetry of the device, W₁=W₂, the total current is zero.

Under high applied voltages, the depletion field from the cathode extends (reaches through) that of the anode, making it effectively zero. The total current in this situation saturates with its only dependency on the total distance between the electrodes and the carriers generation rate, as shown in Eq. (S15).

$$J = - q G d \qquad ( S15 )$$

### MXene Polarizer Disclosure

Over the past two decades, rapid improvement in tabletop sources of terahertz, THz, radiation have inspired growth in applications of THz technology for materials characterization, pharmaceuticals, imaging, communications and sensing. In addition to reliable sources and detectors, these applications require other active/passive THz optical components, such as linear polarizers for which high extinction ratios and low insertion losses are critical parameters for analyzing the polarization properties of THz signals. Currently, commercially available THz polarizers are either free-standing or supported metallic wire grids, commercialized by Tydex and Microtech® Instruments. Free-standing polarizers have high, ˜20-40 dB power extinction ratios and low insertion losses, but are expensive and fragile.6 Substrate-supported metal, typically Al, wire grid polarizers are more robust and can be produced by photolithography, hot embossing, etching or nanoimprinting, and have been recently successfully demonstrated on a flexible substrate, an important step towards conformable THz devices.

Inherent anisotropic conductivity of 1D nanostructures such as semiconducting or metallic nanowires, or carbon nanotubes, has motivated efforts to design THz polarizers based on highly aligned nanowire or nanotube arrays. These structures achieve high performance characteristics, and, in the case of semiconductor nanowires, are dynamically switchable. However, achieving high degrees of alignment of nanowires or nanotubes over macroscopic regions remains challenging.

Here, we provide broadband THz polarizers based on hydrophilic metallic 2D MXene with metallic conductivity, Ti₃C₂T_{z}. The latter is obtained by selectively etching, mostly Al layers from an exemplary, non-limiting parent Ti₃AlC₂ MAX phase and replacing them with O, OH and/or F-terminations, labeled as T_{z} in the chemical formula. Discovered eight years ago, they combine metallic conductivity, excellent mechanical properties, and ease of processing owing to the hydrophilicity of their surface termination groups. The 2D solids, have already inspired a host of applications that leverage their high electrical conductivities (˜1000-8000 (Ωcm)⁻¹) such as transparent flexible conductors, THz detectors and electromagnetic interference (EMI) shielding in the gigahertz, GHz, and THz frequency ranges. In fact, Ti₃C₂T_{z} films have been shown to exceed EMI shielding efficiency of carbon nanostructures and their composites, and perform comparably to copper and silver all while being significantly more lightweight.

MXene patterning had previously been carried out using laser printers, or microcontact printing techniques, with large feature sizes. We have recently shown that MXene photodetectors that outperform more standard Au-based ones can be fabricated by simply spin-coating transparent Ti₃C₂-based MXene electrodes from aqueous suspensions onto a substrate patterned with photoresist, followed by immersion in acetone.

Here, we demonstrate that very thin (˜30 nm), 10-20 μm wide striations of spin coated Ti₃C₂T_{z}, consisting of overlapping nanosheets that are 1-3 μm in lateral dimensions, exhibit excellent polarization properties over the 0.3-2.0 THz spectral range, with electric field extinction ratios (ERs) of up to 3 dB, corresponding to power ERs of 6 dB. Using simulations, we further show that increasing the line thicknesses to 1.5-2 μm, and optimizing the periods and fill factors of the periodic striations can increase ER to >16 dB for electric field or >32 dB for power, while maintaining low insertion losses.

Encapsulation in flexible layers of polydimethylsiloxane (PDMS) or other THz-transparent material instead of depositing them on a quartz substrates as done here, can result in flexible, free-standing thin layers that can be stacked to achieve high extinction ratios while maintaining low insertion loss, low weight, and chemical stability. Moreover, possibility of dynamical control over Ti₃C₂T_{z} THz conductivity that has been recently demonstrated, suggesting that dynamically tunable polarizers for high-speed THz devices can be achieved.

### Experimental Details

The Ti₃C₂T_{z} MXene polarizer devices 2×2 mm² comprised of parallel line patterns were deposited on quartz substrates using conventional photolithography and a simple fabrication process. Performance of the devices was evaluated using a standard THz time-domain spectroscopy (THz-TDS) experiment, accompanied by the simulations using Comsol Multiphysics.

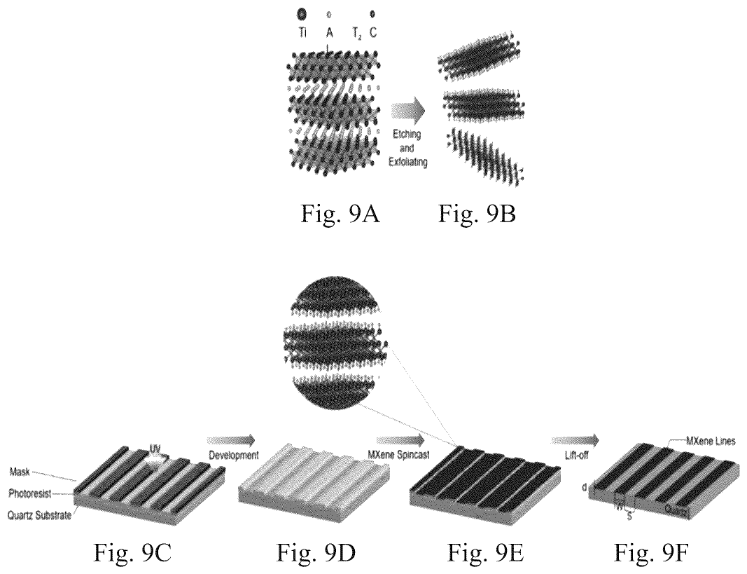

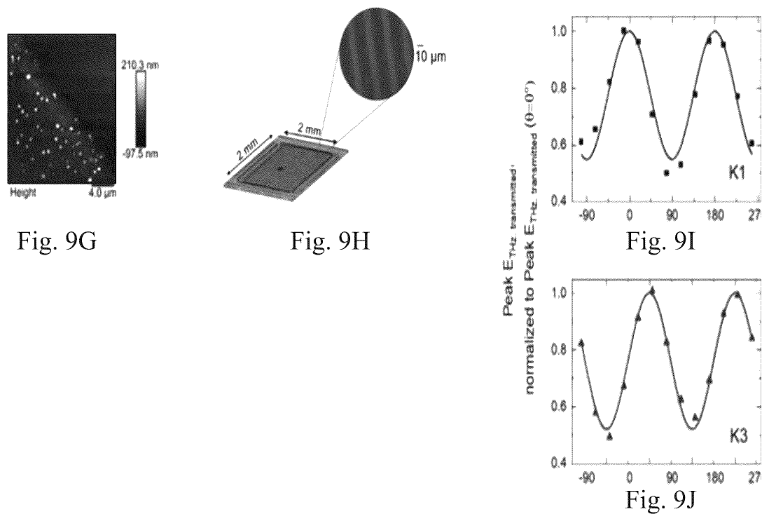

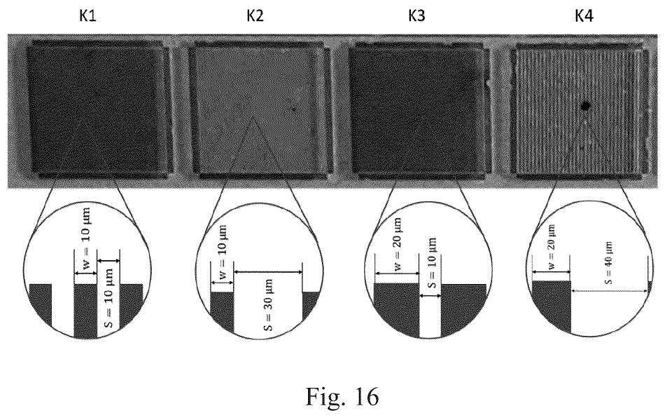

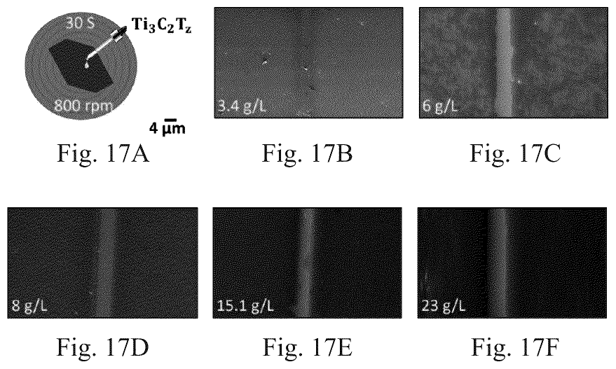

Device fabrication is shown in FIGS. 9A-9I, where first the Ti₃AlC₂ MAX phase (FIG. 9(A)) was etched and delaminated to obtain a colloidal aqueous suspension of Ti₃C₂T_{z} single flakes (FIG. 9(B)), as described in detail elsewhere herein. Several patterns of striations with various width (w=10 μm and 20 μm), separated by spaces, s=10 μm, 30 μm and 40 μm were formed using photoresist and conventional contact lithography on quartz substrates (FIG. 9(C)) and developed (FIG. 9(D)). Detailed description of the photolithography procedure is given FIGS. 16 and 17A-17F.

The MXene colloidal suspension was then spin cast on the substrate (FIG. 1E). Lastly, the photoresist was removed by immersing the device in acetone (FIG. 9(F)) in a conventional lift-off process, leaving MXene striations covering a 2×2 mm² area (FIG. 9(G)). Thicknesses of the resulting lines were measured using atomic force microscopy (AFM) using a tapping of the probe at ambient conditions and was found to be ˜30 nm (FIG. 9(H). The sharpness of the edges, seen in AFM and scanning electron microscopy (SEM, FIG. 9(I)) images indicate that the resolution of this method is primarily limited by lithography, as discussed in more detail elsewhere herein. This room-temperature ambient-condition lift-off process does not require high vacuum, high temperature deposition chambers, nor plasma (dry) etching capabilities. It is also compatible with common microfabrication techniques including photonic integrated circuits and silicon photonics.

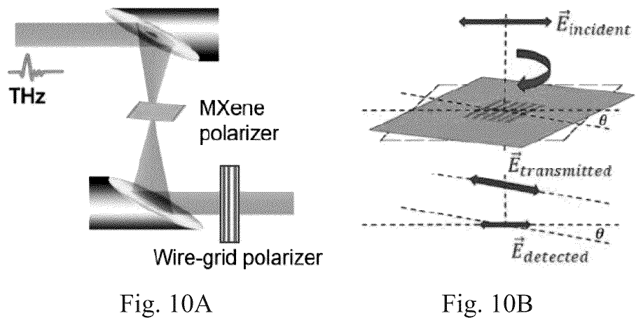

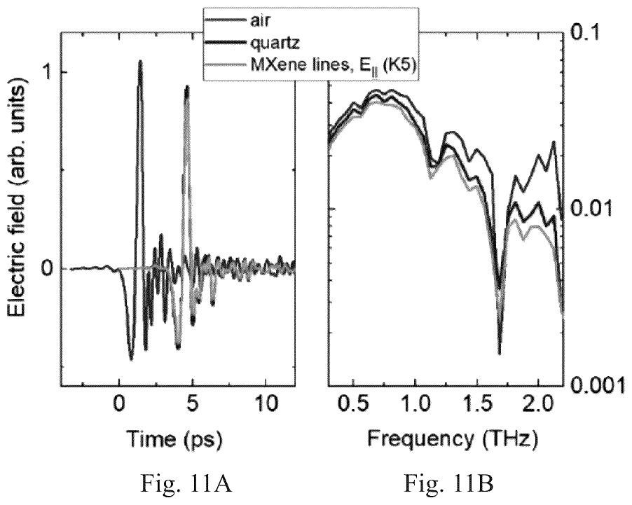

We evaluated the performance of the polarizers using a conventional THz TDS setup. THz pulses were generated by the optical rectification of 100 fs, 800 nm pulses from a 1 kHz repetition rate amplified Ti:S laser (Coherent Libra®) in a 1 mm-thick ZnTe crystal. The THz pulses were focused to ˜1.5 mm spot on a polarizer device using an off-axis parabolic mirror, and the transmitted pulses were collected by another off-axis parabolic mirror and coherently detected by free-space electro-optic sampling in a second 1 mm-thick ZnTe crystal (FIG. 10(A)). The wire-grid polarizer (Microtech Instruments; field extinction ratio of 0.01) ensured that only the component of the transmitted pulse that was parallel to the incident pulse polarization was detected. The orientations of the samples were varied by rotating the samples by an angle θ (FIG. 10(B).

An example reference THz pulse that propagated through air without the sample in its path, along with the pulses transmitted through the quartz substrate and through one of the polarizer structures with lines oriented along the polarization of the THz probe pulse are shown in FIG. 11(A); the corresponding THz amplitude is shown in FIG. 11(B). The ˜1 mm thick quartz substrate with a refractive index of 2.156 at 1 THz³⁶ introduces a significant delay in the arrival of the probe pulse, and attenuates the transmitted pulse due to reflection losses. The insertion loss due to a quartz substrate, defined as

$${IL}_{q u a r t z} = - 10 log ( \frac{{E}_{quartz}}{{E}_{ref}} ) ,$$

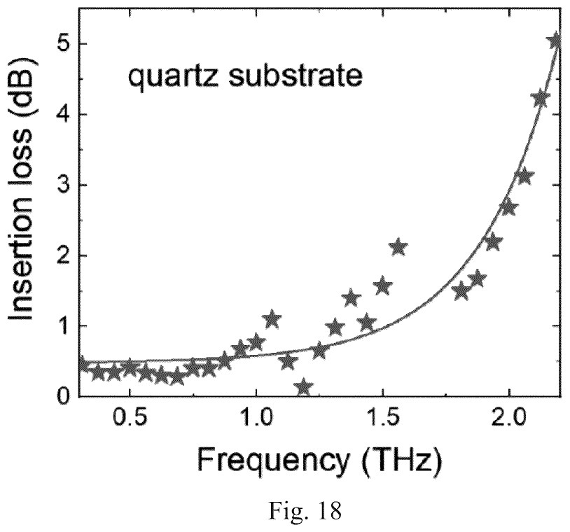

is ˜0.6 dB at 1 THz, as shown in FIG. 18. For future applications, THz-transparent flexible substrates with lower refractive indices can be used to minimize insertion losses. In the following analysis, we focus on the insertion loss introduced by the MXene structures alone, treating the THz pulses transmitted through the quartz substrate as a reference. Dips in the THz amplitudes at ˜1.15 THz and ˜1.7 THz are due to strong absorption of THz radiation by water vapor in ambient air which results in a reduction of the signal to noise ratio in the vicinity of those frequencies.

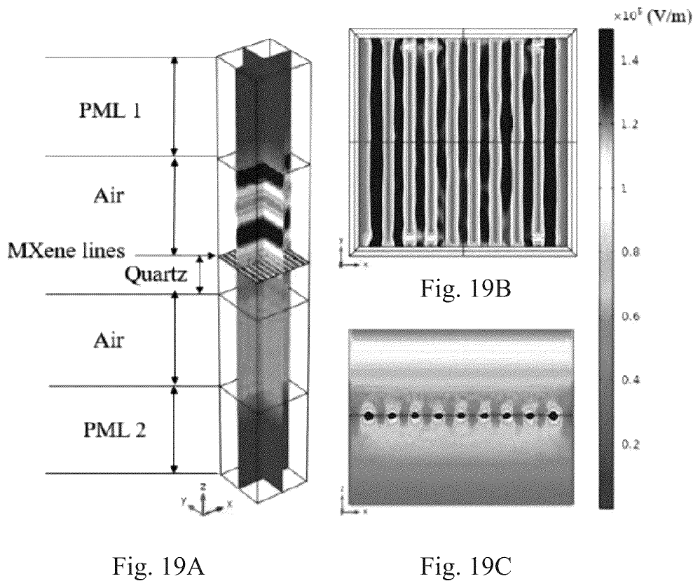

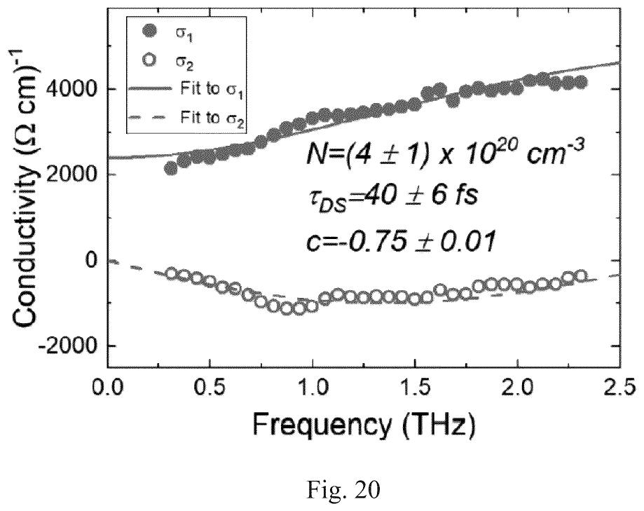

Finite-difference time-domain (FDTD) simulations of our Ti₃C₂T_{z} polarizer performance at 1 THz as a function of period (w+s), fill factor (w/(w+s)), and line thicknesses were carried out using the RF module of the commercial solver Comsol Multiphysics, as described in more detail elsewhere herein (FIG. 19A-19B). The properties of Ti₃C₂T_{z} in the THz range were parameterized using a Drude-Smith model,^{37,38} following previous reports.^{31,32,39} To model the polarizers, we assumed a carrier density of 4×10²⁰ cm⁻³, a scattering time of 40 fs, and a Drude-Smith c-parameter of −0.75, representing the effect of Ti₃C₂T_{z} nanoflake boundaries and disorder on the long-range electron transport. Details of the Drude-Smith analysis are provided elsewhere herein (FIG. 20).

### Results and Discussion

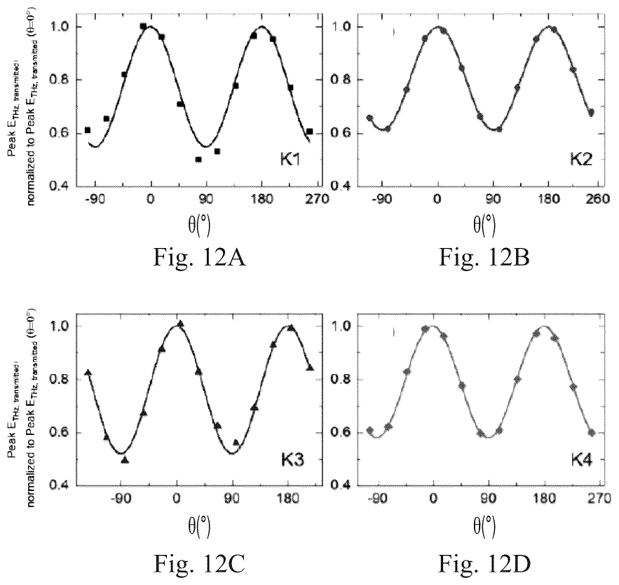

Rotation of the polarizer structure about the normal through an angle θ (FIG. 10A-10B) results in a characteristic Malus's law cos²(θ) dependence, as shown in FIGS. 12A-12D, which plots the peak of the transmitted pulse as a function of angle for four different polarizer structures K1 (w=10 μm, s=10 μm), K2 (w=10 μm, s=30 μm), K3 (w=20 μm, s=10 μm), and K4 (w=20 μm, s=40 μm). The resulting peak degrees of polarization, defined as

$$\frac{{E}_{⊥} - {E}_{‖}}{{E}_{⊥} + {E}_{‖}} ,$$

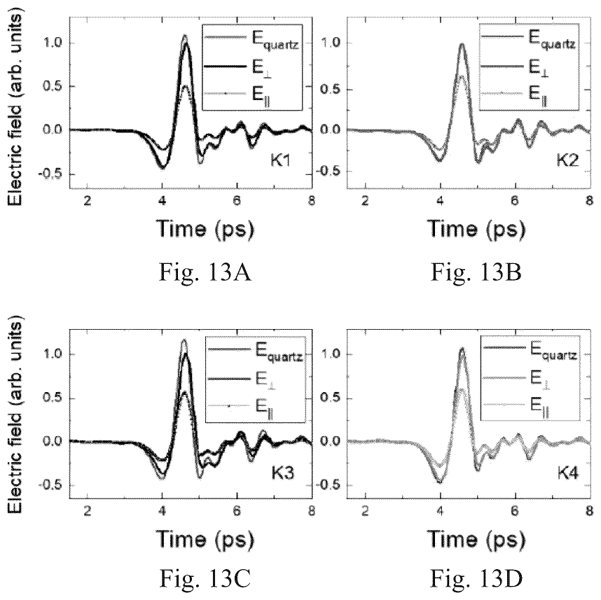

range from ˜30% for K1 and K3, down to 27% for K4 and 24% for K2. The entire time domain waveforms for the electric field of the incident THz pulse parallel and perpendicular to the polarizer lines, for all four structures, are shown in FIGS. 13A-13D, where the reference THz pulses transmitted through the quartz substrate are also shown. The frequency-resolved THz amplitudes of the waveforms in FIGS. 13A-13D are then used to calculate the electric field extinction ratios

$$( E R = 10 log ( \frac{{E}_{⊥}}{{E}_{‖}} ) )$$

and insertion losses

$$IL = - 10 log ( \frac{{E}_{⊥}}{{E}_{quartz}} ) ,$$

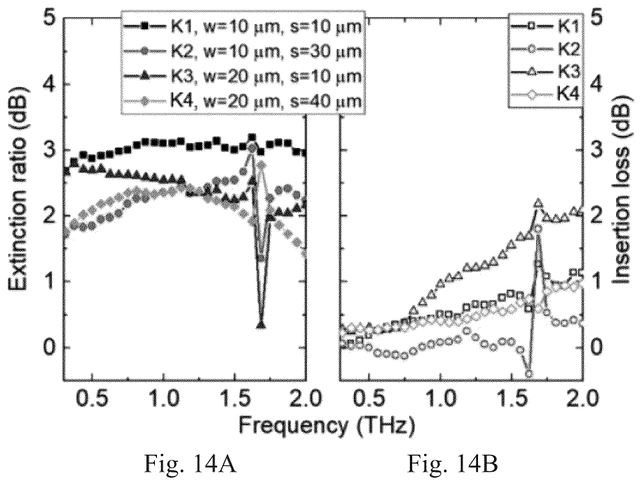

which are plotted in FIGS. 14A-14B as a function of frequency. While the demonstrated ER values are significantly lower than those for commercially available structures (10-20 dB for electric field, or 20-40 dB for power), we stress here that the thickness of MXene lines in the polarizers studied here is only ˜30 nm, compared to ˜20-40 μm thick metal wires that are typically used in commertial wire-grids. In fact, for the best performing structure (K1), ER is only ˜factor of 2 lower that that demonstrated for single layer, 2 μm thick carbon nanotube polarizers. Comparing the performance of the four structures, we observe that the narrower lines (10 μm vs. 20 μm), and narrow gaps (10 μm) yield the best compromise between the ER and IL. The wider lines with the same gap (K3), result in a higher area filling fraction (⅔ vs ½), IL increases without gain in ER. For the lower filling fractions, ER is reduced.

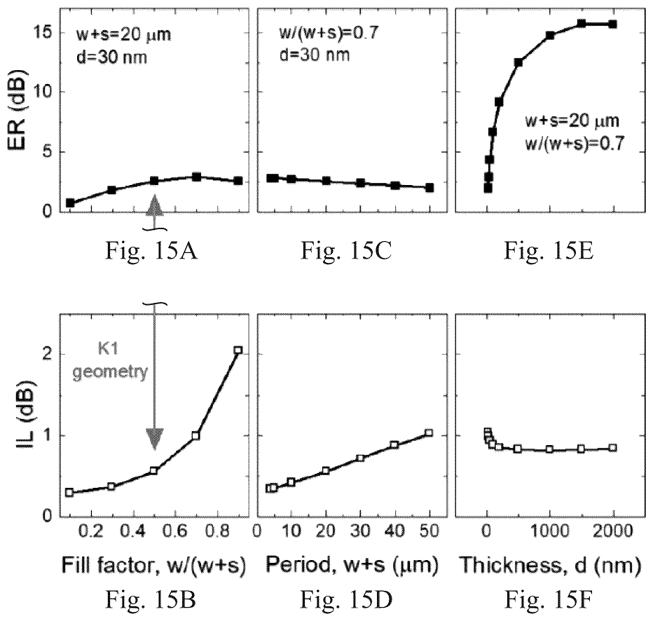

To further explore how the MXene polarizer performance can be optimized by geometry, such as varying the period, filling fraction, or line thickness, we carried out FDTD simulations at a frequency 1 THz (FIGS. 15A-15F). For periods of 20 μm, filling fractions of 0.5 and line thicknesses of 30 nm-corresponding to the K1 polarizer geometry—our simulations yield ER of 2.6 dB and IL of 0.6 dB (FIG. 15(A,B)), in good agreement with experimental results (FIGS. 14A-14B). We attribute small deviations of the experimental results from the simulations to inhomogeneities in the fabricated devices. As expected, we find that increasing the filling factor by increasing the line width w, while keeping the period constant, increases the insertion losses. The extinction ratio increases up to filling fraction of ˜0.5-0.7. If the filling fraction is fixed at the near optimal value of 0.7, we find that narrower lines are more desirable, as they minimize insertion losses alongside a modest improvement in extinction ratios. Finally, we find that increasing the line thickness dramatically improves polarizer performance, with electric field extinction ratio saturating at ˜16 dB when for thickness of ˜1 μm. The optimal MXene polarizer thickness agrees well with a calculated Ti₃C₂T_{z} skin depth at 1 THz,

$$δ = \sqrt{\frac{2}{ω {μ}_{0} σ}} \approx 0.9 μm ,$$

where μ₀ is vacuum permittivity, ω/2π=1 THz, σ(1 THz)˜5000 (Ωcm)−1 (FIG. 20).

In conclusion, we have demonstrated proof of concept of a THz polarizer based on parallel lines of overlapping Ti₃C₂T_{z} nanosheets that are solution-processed and can be deposited on a variety of substrates. Lines only 30 nm thick yield electric field ERs of up to 3 dB, or power ERs of up to 6 dB. Simulations show that ER can be increased up to >16dB for electric field, or >32 dB for power by increasing the line thickness to 1.5-2 μm, with line widths of 10 μm or less, and area filling fractions in the 0.5-0.7 range giving the optimal results. The projected performance is comparable to commercial polarizers at a fraction of a cost and thickness. One can increase the thickness of the optimized devices by stacking multiple layers of MXene lines on THz-transparent, flexible substrates such as PDMS or TPX, which can also serve to encapsulate the MXene structures to prevent their oxidation. Finally, we have recently demonstrated that optical pulses (800 nm or 400 nm) can dynamically reduce the THz conductivity of Ti₃C₂T_{z} MXene, with conductivity suppression onset over sub-picosecond timescales, and suppression lasting over nanoseconds time scales. This possibility of dynamically controlling conductivity in MXene polarizer for nanoseconds at a time provides opportunities for the development of high-speed THz modulator devices.

### Synthesis of Ti₃C₂T_{z} Colloidal Suspension

The precursor Ti₃AlC₂ powder was synthesized by heating a ball-mixed mixture of TiC, Al and Ti (Alfa Aesar, 99.5% purity) powders in a molar ratio of 2:1.05:1, respectively, in argon, Ar, atmosphere at a rate of 5° C./min to 1350° C. and holding at temperature for 2 h. The resulting solid is milled and sieved (−400 mesh) to obtain a powder with particle size under 38 μm. Then 1 g of LiF (Alfa Aesar, 98% purity) is dissolved in 10 mL of 12 M HCl (Fisher Scientific) into which 1 g of Ti₃AlC₂ (sieved to <38 μm) is slowly added. The solution was stirred at 35° C. for 24 h. After etching, the powder was washed eight times with distilled water in a centrifugation and decantation process (3500 rpm, 2 min) until the supernatant reached a pH of ˜5 and spontaneous delamination was observed. 20 mL of distilled water are then added to the sediment and the mixture is sonicated for 1 h at room temperature, RT, under bubbling Ar. The solution is then centrifuge at 3500 rpm for 1 h. The supernatant collected contained mostly single Ti₃C₂T_{z} single flakes. The concentration of flakes in the solution (23 g/L) was determined by vacuum filtering a given volume solution, drying the resulting film and weighting it.

### Pattern Production using Photolithography

Quartz substrates were cleaned under sonication in alkaline detergent (2 times, 2 mins each time), followed by acetone, methanol, isopropanol wash, each for 1 min. Positive photolithography was performed on samples with spincast of microposit S1813 that was 2 μm thick. Once deposited, the film temperature was raised to 115° C. for 150 s using a hot-plate. Microposit UV exposure at

$$170 \frac{j}{{cm}^{2}}$$

for 5 s using a contact mask aligner was performed. Chemical development was carried out using Microposit MF CD-26 developer for 60 s, rinsed and dried. Films of Ti₃C₂T_{z} were spin-cast on all substrates at 800 rpm for 30 s using a colloidal suspension of single flakes (23 g/L) The photoresist was removed by immersion of the sample in acetone for 30 s, and sonicated in an ice bath for 10 s, then dried, resulting in printed MXene structures. The thicknesses of the resulting lines were measured using atomic force microscopy using tapping of the probe at ambient conditions, and was found to be ˜30 nm. Optical images of the resulting polarizer structures are given in FIG. 16.

### Fabrication of Patterned Substrate with Various Thicknesses

In this disclosure we have tested and measured the characteristics of devices fabricated on Quartz substrate with the thickness of approximately, 30 nm. However, FDTD simulations shows that the extinction ratio of the MXene polarizer, improves with thicker films. In order to confirm this hypothesis, we have fabricated thicker films using spin cast of various concentrations of Ti₃C₂T_{z} on the substrates. Higher concentration of solid in the colloidal suspension, results in thicker films. The resulting films and patterns, mostly suffered from non-uniformity and lower yield of the desired patterns on the wafer. Further study on the best methods of deposition for producing thick uniform films is needed. We are currently working on spray coating a low concentration suspension for long period of time to achieve uniform, but tightly aligned MXene flakes which will offer better conductivity along with more thickness of the patterns of the wafer. Another technique for achieving thicker wires is to encapsulate the wires in PDMS and stack up multiple layers to get an effectively thicker wires in the polarizer.

FIGS. 17A-17F show the edges of the wires of MXene produced with various concentration of solids, for a spacing of 4 μm between the lines, after spin cast and lift off with acetone.

### Insertion Loss of a Quartz Substrate

### Comsol Simulations

The FDTD simulations were performed using Comsol Multiphysics

assuming periodic boundary conditions and perfectly matched layers (PML). Response of Ti₃C₂T_{z} to the incident plane monochromatic electromagnetic waves was modeled within the framework of the Drude-Smith conductivity model, as discussed below. Response of the quartz substrate was modelled assuming the average refractive index is 2.156 in the 0.5-1.5 THz range,³⁶ and a negligible absorption coefficient. Neglecting substrate absorption allowed us to set the thickness of the quartz layer in the simulations to 10 μm to avoid Fabri-Perot interference effects when simulating the response of the polarizer structure to plane monochromatic waves.

Response of real structures was measured using short THz pulses, and Fabri-Perot effects play no role as pulses reflected multiple times at quartz interfaces were well separated in the time domain. Since the thickness for the MXene layer is small comparing with the lateral line width and gap between the lines, transition boundary condition were assumed to decrease the calculation times. The linearly polarized THz waves—with fixed frequencies in the THz range—were incident via PML1, and exit through PML2, respectively. FIG. 19(B,C) shows an example of the instantaneous electric field distribution in x-y and x-z planes for the incident wave that is polarized at 45° with respect to the MXene lines. In FIG. 19(B), a significant reduction in electric field is seen behind the wires (blue areas) due predominantly to the THz absorption and reflection by the MXene lines. Enhancement of the electric field in the gaps between the lines is also seen.

### Modeling Properties of Ti₃C₂T₂ MXene in the THz Range

Individual Ti₃C₂T_{z} nanoflakes of up to ˜3 μm lateral dimentions are metallic, but the THz conductivities of films comprised of multiple overlapping nanoflakes is suppressed at low frequencies by interflake barriers.^{31,32} The film conductivities, however, are well-described by a Drude-Smith conductivity, modification of the free electron gas Drude model. The complex free carrier conductivity is given as

$$\tilde{σ} ( ω ) = \frac{{σ}_{0}}{1 - i ω {τ}_{D S}} ( 1 + \frac{c}{1 - i ω {τ}_{D S}} ) ,$$

where

$${σ}_{0} = \frac{N {e}^{2} {τ}_{D S}}{{m}^{*}}$$

is the Drude weight, τ_{DS} is a carrier scattering time, N is the charge carrier density, and m* is the carrier effective mass. The phenomenological c-parameter varies in the −1≤c≤0 range and accounts for the impact of barriers such as nanoflake edges and defects on long-range carrier transport. For c=0, carrier transport follows the classical Drude model, and when c=−1, the carriers are fully localized over short distances, resulting in complete suppression of conductivity at ω=0.

Depending on preparation and morphology, the carrier densities in Ti₃C₂T_{z} films can reach ˜2×10²¹ cm³, scattering time is on the order of tens of fs, and the c-parameter ranges from −0.97 in films, with <1 μm flakes separated by gaps to −0.69 in continuous films of overlapping flakes.^{31,32} Here, we have established the model parameters by fitting the THz conductivity conductivity in K3 polarizer with the highest area coverage, using THz probe pulses that are parallel to the Ti₃C₂T_{z} lines in order to probe the motion of carriers within the lines. The complex conductivity is shown in FIGS. 19A-19B. The fitting parameters are given in the figure legend, and are consistent with previous reports. Carrier density was determined using a zone-center electron effective mass of 0.2845 mₑ.

### Additional Disclosure—MX-S-MX/BE Devices

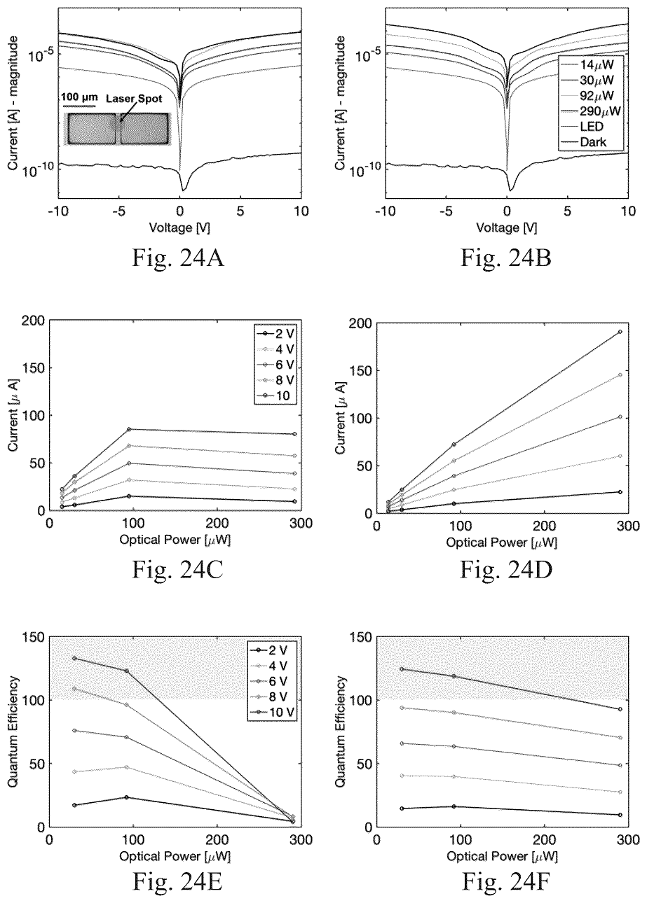

I-V characteristics of the MX-S-MX/BE device were obtained in two rounds, using a continuous wave laser at 800 nm wavelength, and a picosecond laser at the same frequency. FIGS. 24A-24B show the I-V curves of the detector under sweeping optical powers from 15 to 300 sourced from a continuous wave laser, and a picosecond pulse laser in addition to under LED light. The inset shows the device image under an optical microscope, as well as the illumination area and the laser spot size. The photoresponse under illumination using the picosecond laser is shown in FIG. 24B. The photocurrent generation is shown to be even stronger and up to two orders of magnitude higher than the MX or Au GaAs-based detectors.

By obtaining the photo response under sweeping optical powers, responsivity and external quantum efficiency of this detector were calculated for both rounds of measurements. FIG. 24C, and FIG. 24D demonstrates the photocurrent responses of the detector versus input power for CW and ps laser sources, respectively.

FIGS. 24E and 24F show the calculated values for the external quantum efficiency per incident photon under illuminations from both sources. Comparing the quantum efficiency of this device with the previously reported cases, in addition to significant improvement over MX-GaAs-MX devices and Ti/Au-based MSMs, we observe an internal gain which leads to higher that 100% external quantum efficiency.

Table 5 below provides figures of merit for MX-S-MX-BE photodetectors at 2, 4, 6, 8, 10 V bias under optical illumination of 30, 90, and 290 μW power from 800 nm laser sources, and comparison with MX-GaAs-MX under 780 and 830 nm wavelengths sources under 300 μW power and various biases:

| | | MX · 8 · MX/BE | | | | | | MX · S ·MX | |
|---|---|---|---|---|---|---|---|---|---|
| | | 800 nm | | | | | | 780 mm | 830 nm. |
| | Bias | Power CW Laser [μW] | | | Power ps Laser [μW] | | | Power ps | Laser [μW] |
| Figure of Merit | [V] | 30 | 90 | 290 | 30 | 90 | 200 | 300 | 300 |
| R [mAW⁻¹] | 2 | 110.5 | 150.9 | 28. 7 | 94.5 | 104.5 | 62.3 | 24 | 32 |
| | 4 | 281.1 | 304.6 | 47.0 | 262.0 | 237.7 | 179.0 | 50 | 86 |
| | 6 | 490.6 | 457.0 | 54.4 | 425.6 | 409.8 | 314.6 | 106 | 170 |
| | 8 | 702.7 | 621.2 | 52.6 | 606.7 | 582.2 | 455.6 | 195 | 278 |
| | 10 | 857.5 | 793.4 | 25.5 | 802.7 | 766.1 | 598.5 | — | — |
| QE [%] | 2 | 17.1 | 23.4 | 4.4 | 14.6 | 16.2 | 9.6 | 3.8 | 4.7 |
| | 4 | 43.5 | 47.2 | 7.2 | 40.6 | 30.9 | 27.7 | 7.9 | 12.8 |
| | 6 | 76 | 70.8 | 8.4 | 65.9 | 63.5 | 48.7 | 16.8 | 25.4 |
| | 8 | 108.9 | 96.2 | 8.1 | 94.0 | 90.2 | 70.6 | 31 | 41.5 |
| | 10 | 132.9 | 122.9 | 3.9 | 124.4 | 118.7 | 92.7 | — | — |
| D+ [Jones] × 10¹⁰ | 2 | 4.8 | 6.6 | 1.2 | 4.1 | 4.6 | 2.7 | 1.0 | 1.4 |
| | 4 | 12.4 | 13.4 | 2.0 | 11.5 | 11.4 | 7.9 | 2.2 | 3.8 |
| | 6 | 21.6 | 20.2 | 2.4 | 18.8 | 18.1 | 13.9 | 4.6 | 7.5 |
| | 8 | 31.0 | 27.4 | 2.3 | 26.8 | 25.7 | 20.1 | 8.6 | 12.3 |
| | 10 | 37.8 | 35.0 | 1.1 | 35.4 | 33.8 | 26.4 | — | — |
| $NEP [ \frac{w}{\text{?}} ] \times {10}^{- 14}$ | 2 4 | 5.1 2.0 | 3.7 1.8 | 19.7 12.0 | 6.0 2.1 | 5.4 2.2 | 9.0 3.1 | 23.5 11.3 | 17.7 6.5 |
| | 6 | 1.1 | 1.2 | 10.4 | 1.3 | 1.3 | 1.8 | 5.3 | 3.3 |
| | 8 | 0.8 | 0.9 | 10.7 | 0.9 | 0.9 | 1.2 | 2.9 | 2.0 |
| | 10 | 0.6 | 0.7 | 22.1 | 0.7 | 0.7 | 0.9 | — | — |
| DR [dB] | 2 | 87.6 | 93.8 | 91.6 | 87.0 | 92.3 | 95.0 | 91.0 | 92.3 |
| | 4 | 91.7 | 98.7 | 93.8 | 91.4 | 96.2 | 99.6 | 94.2 | 96.6 |
| | 6 | 94.1 | 98.7 | 94.4 | 98.5 | 98.2 | 102.0 | 97.5 | 99.5 |
| | 8 | 95.7 | 100.0 | 94.3 | 95.0 | 99.7 | 103.6 | 100.1 | 101.7 |
| | 10 | 96.5 | 101.1 | 91.1 | 96.3 | 100.9 | 104.8 | — | — |

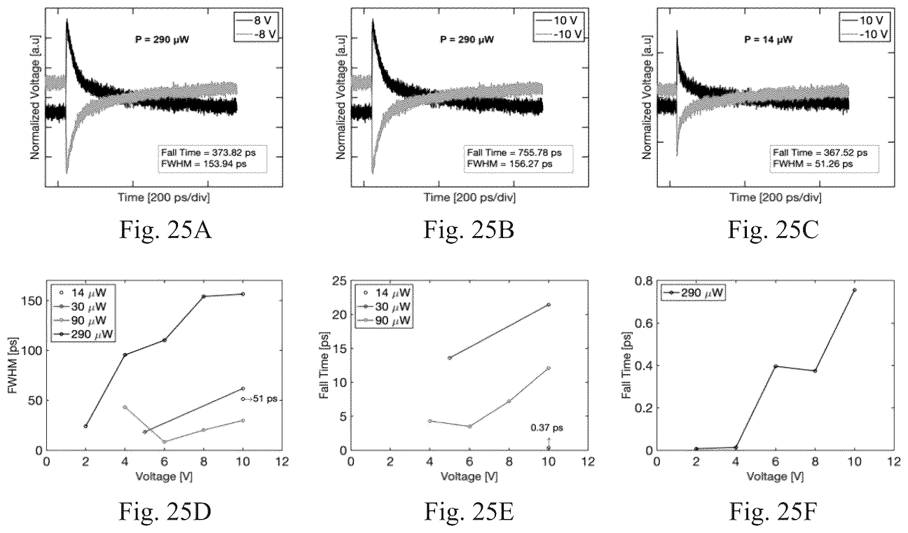

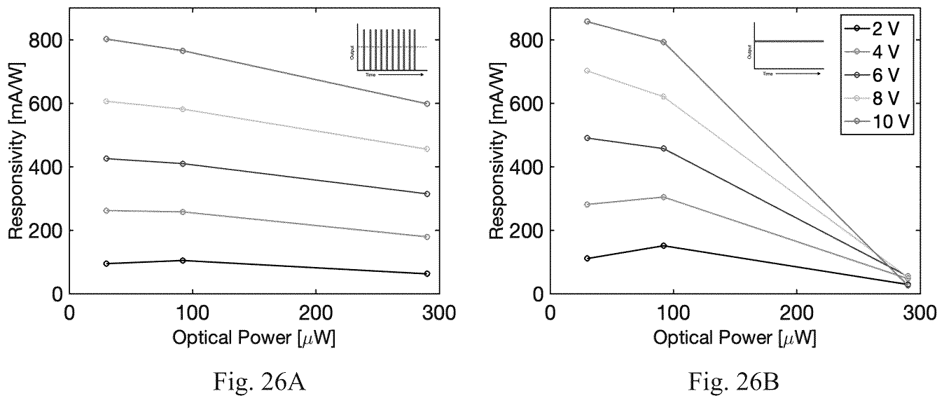

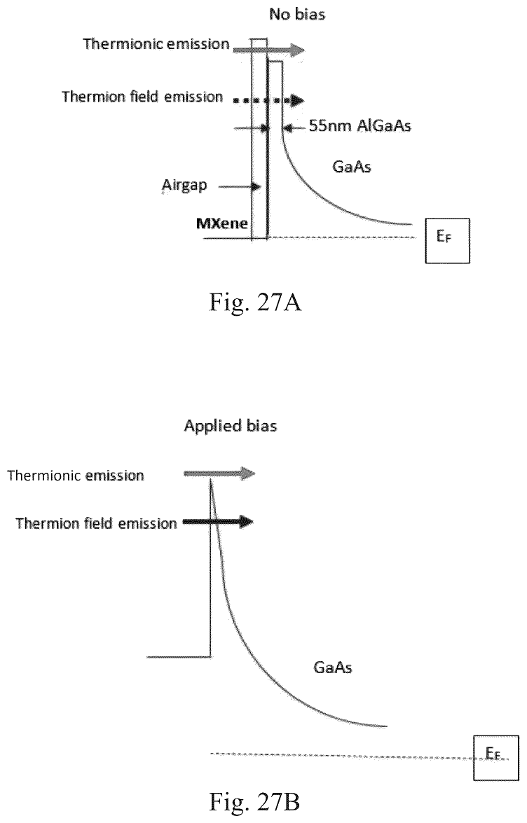

FIGS. 25A-25F provide the time responses under various optical powers, showing order-of-magnitude higher speeds than comparable devices. FIGS. 26A-26B provide responsivities (for the discloses devices) that are among the highest reported, and FIGS. 27A-27B provides energy band diagrams for devices according to the present disclosure.

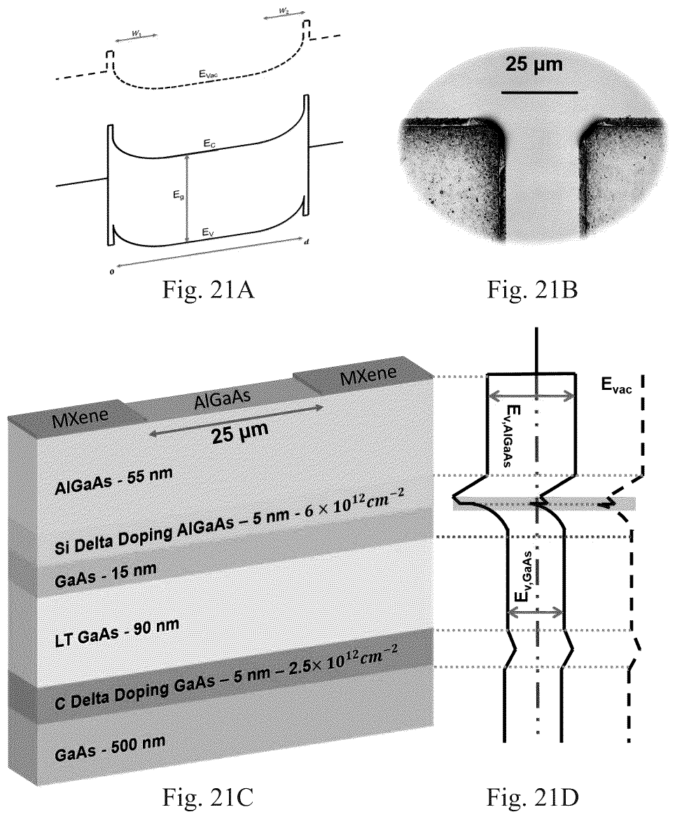

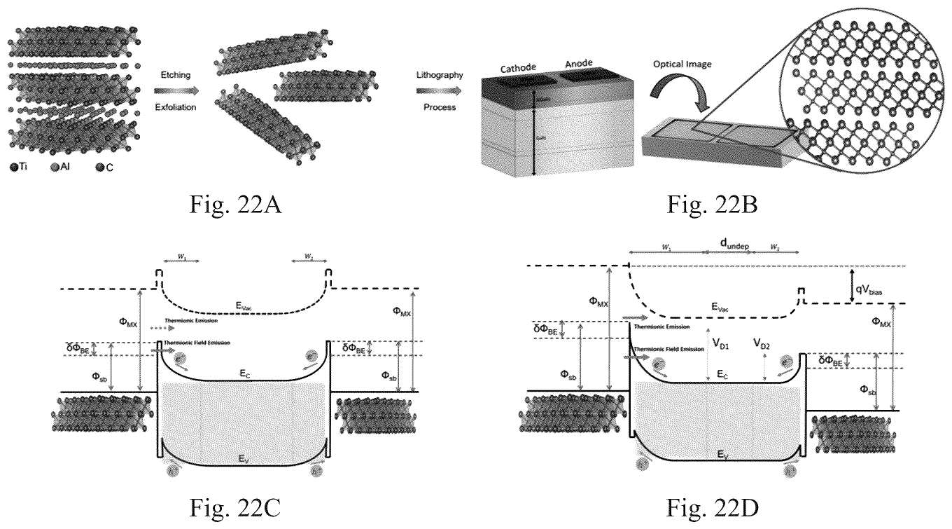

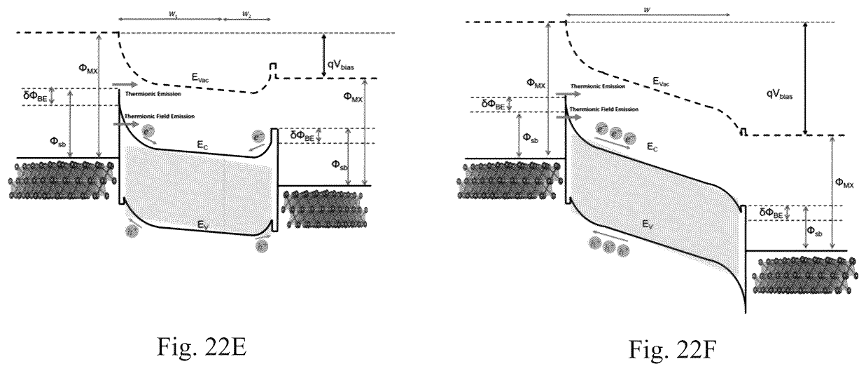

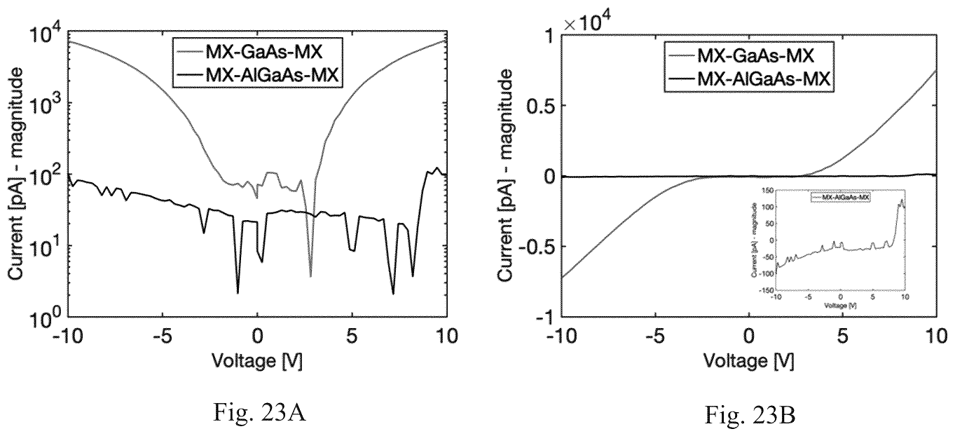

By reference to non-limiting FIG. 21C, the AlGaAs (Al_{.35}Ga_{.65}As) material is a wide bandgap material with bandgap (Eg) of ˜1.8 eV (determined by the mole fraction 0.35), that makes a heterojunction with GaAs (Eg=1.42 eV). This material can play the role of barrier enhancement. The example width of 55 nm is chosen to be similar to high electron mobility transistor (HEMT) structures so as to be wide enough to avoid tunneling and narrow enough to allow for carriers with enough kinetic energy to overcome the barrier. (FIGS. 27A-27B provide an energy barrier diagram for this configuration.)

Without being bound to any particular theory, because MXene is drop cast or spun-on the substrate, it does not necessarily form chemical bonds with the crystal surface of the semiconductor, rather produces a van der Waals (vdW) junction that is different from a junction that deposited metal makes. Again without being bound to any particular theory or embodiment, MXene has an airgap to AlGaAs which in turn makes a heterojunction with GaAs. Dark current is the thermionic emission current shown by the arrows in FIGS. 27A-27B, which consists of electrons that can overcome the AlGaAs barrier of ˜1.2 eV. Without AlGaAs this barrier would be that of GaAs=˜ 0.95eV. This in turn theoretically causes a reduction in current of exp[(1.2−0.95)/0.0259]=˜15,000. One sees an impressive factor of 200 reduction in dark current in the data, and can (though without being bound to any particular theory or embodiment) explain the discrepancy to the role of thermionic field emission, which is tunneling by electrons that have energy above the Fermi level, as shown in FIG. 27B.

Again in relation to exemplary FIG. 21C, the AlGaAs mole fraction of 0.35 (for Al) was chosen to lattice match GaAs, although other mole fractions can be used. The other layers of the structure were designed so as to establish a vertical electric field that moves the electrons upward towards the contacts and collects them in a sea of confined electrons thus improving response speed. Without being bound to any particular theory, the transparent MXene contact to AlGaAs, as detailed above is the reason for this enhancement; besides being transparent, MXene contacts offer a different physics as explained herein, which different physics is leveraged here and has not been previously attempted.

Without being bound to any particular theory or embodiment, the unexpected performance of the disclosed devices can be accomplished with (1) a comparatively wide bandgap AlGaAs (e.g., appx. 50 nm thick,) barrier enhancement layer (superposed on which are MXene contacts); and (2) a GaAs (e.g., appx. 1 um thick) absorption region heterojunction, which features can act to decrease dark current, thereby increasing dynamic range and signal-to-noise ratio. Again without being bound to any particular theory or embodiment, doping the AlGaAs will increase the speed of response.

It should be understood that MXenes (e.g., Ti₃C₂T_{z}) has the attribute that their work function can be adjusted (e.g., from 2.14 eV to 5.65 eV) by different means, e.g., hole injection or surface termination using oxygen, fluorine, or chlorine. This provides a wider range compared to all metals used in as Schottky contacts. Consequently, if the Fermi level is not pinned in the semiconductor, as is the case in silicon, MXenes can be used as ohmic or Schottky contacts, essentially at will. In this way, one can form a MESFET structure in silicon where MXenes of comparatively higher work function are used as the (transparent) gate material, while MXenes of comparatively lower work function can be used as source and/or drain Ohmic contacts.

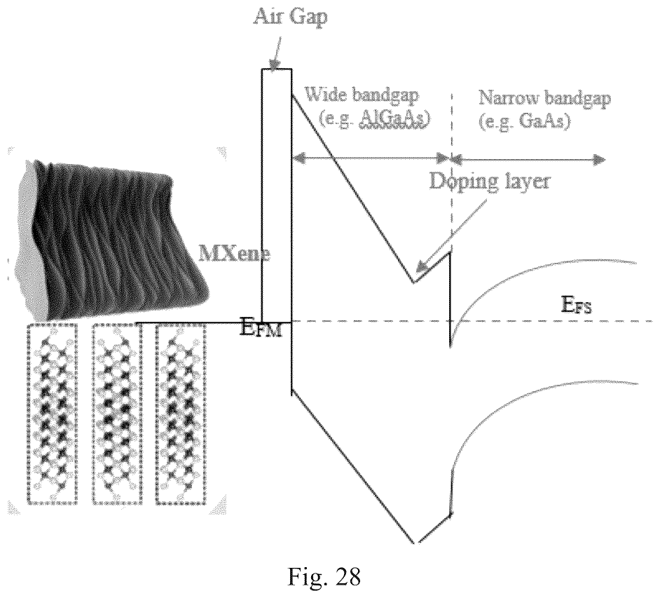

Furthermore, metal contacts to the so-called III-V semiconductors (which include binaries such as GaAs, InP, GaN, and the like; and also ternaries such as AlGaAs, AlGaN, InGaAs, and the like; and also quaternaries, such as InGaAsP, and the like) are known for a barrier height between the metal and semiconductor that is essentially independent of the metal work function, since the semiconductor Fermi level is pinned within its bandgap. This so-called Fermi-level pinning can be detrimental to operation of both Schottky (photo) diodes and Schottky gates of MESFETs and HEMTs, where a large barrier height is desirable but cannot be achieved since all metal, regardless of their work function will have the same barrier. The case of MXene contact to GaAs and other III-Vs is different due to the vdW junction as seen in FIGS. 27A, 27B. Hence MXenes offer the ability to change the barrier height by changing MXene work function. This can make MXene-based transistors and Schottky diodes superior to metal-based ones. FIG. 28 provides an energy band diagram of a High Electron Mobility Transistor device with a transparent MXene Schottky (van der Waals) gate.

By reference to FIG. 21C, an AlGaAs layer can define a thickness of from about 20 nm to about 70 nm (including all values and all sub-ranges therein), e.g., 20 to 70 nm, 25 to 65 nm, 30 to 60 nm, 35 to 55 nm, 40 to 50 nm, or even about 45 nm. The Al mole fraction in AlGaAs can be from 0.3 to 0.7, with a fraction of 0.35 for Al being considered especially suitable. (The Ga mole fraction in AlGaAs can be 1—(Al mole fraction), e.g., Al_{.35}Ga_{.65}As.

The AlGaAs region can be doped either uniformly or using a delta doping technique, with the latter being preferable. The delta doping thickness can be 5-15 Angstroms and the doping concentration can be from 1×10¹²-2×10^{12/}cm₂. Uniform doping of AlGaAs can be from 5×10¹⁸ to 10×10^{18/}cm³ (when present).

A GaAs layer can define a thickness of from about 5 to about 15 nm with the aim of producing a high mobility channel for collection and transport of electrons.

A LT (low-temperature) GaAs layer can define a thickness of from about 80 to about 800 nm, including all intermediate values and sub-ranges, e.g., from about 80 to about 800 nm, from about 100 to about 750 nm, from about 150 to about 700 nm, from about 200 to about 650 nm, from about 350 to about 600 nm, from about 400 to about 550 nm, from about 450 to about 500 nm. The total thickness defined in and for GaAs and LT GaAs layers can define a light absorption region. LT-GaAs can be used because it has a comparatively short recombination lifetime and can hence produce extremely fast devices; this means that the optically generated carriers much be collected rapidly. The structure here produces a vertical electric field that pushes the optically generated electron vertically upwards towards the channel, and the slow-moving holes vertically towards the LT-GaAs where they will quickly recombine.

A C Delta Doping GaAs region (if present) can define a thickness of from about 1 to about 2 nm. This region can be p-type doped in order to establish and enhance and electric field in the vertical direction.

The GaAs region can define a thickness of from about 100 to about 2000 nm (including all intermediate values and sub-ranges) and is the substrate for epitaxial growth of layers above. Such a thickness can be, e.g., about 100 to about 2000 nm, about 150 to about 1900 nm, about 200 to about 1800 nm, about 300 to about 1700 nm, about 400 to about 1600 nm, about 500 to about 1500 nm, about 600 to about 1400 nm, about 700 to about 1300 nm, about 800 to about 1200 nm, about 900 to about 1100 nm, or even about 1000 nm.

It is noted that the top barrier enhancement layer can be a comparatively wide-gap (WG) material that is grown on top of a comparatively narrow-gap (NG) material.

The WG material can have a gap that is greater than the gap of the NG material, e.g., greater by 5, 10, 15, 20, 25, 30, 35, 40, 45, 50, 55, 60, 65, 70, 75, 80, 85, 90, 95, 100, 110, 120, 130, 140 150, 160, 170, 180, 190, 200%, or even more (or by any sub-range or combination within the forgoing). Various choices are thus available in different material systems. For example, silicon can be the WG, with SiGe or Ge being the NG. GaAs is a NG substrate for which AlGaAs is a WG of choice. For InP substrates, a InGaAs heterojunction can be used, and for GaN and SiC substrates AlGaN can be used.

### Aspects

The following Aspects are illustrative only and do not serve to limit the scope of the present disclosure or the appended claims.

Aspect 1. A photodetector, comprising:
an assembly that comprises (i) a first semiconducting substrate having a first surface and a second surface; (ii) a first portion of MXene material superposed on a first surface of the semiconducting substrate so as to define a contact between the first portion of MXene material and the first surface of the first semiconducting substrate; and (iii) a second portion of MXene material superposed on the first surface of the first semiconducting substrate so as to define a contact between the second portion of MXene material and the first surface of the first semiconducting substrate,
the first portion of MXene material and the second portion of MXene material being separated from one another by a distance.

Aspect 2. The photodetector of Aspect 1, further comprising a second semiconducting substrate superposed on the second surface of the first semiconducting substrate, the second semiconducting substrate defining a heterojunction with the first semiconducting substrate.

Aspect 3. The photodetector of Aspect 2, wherein the first semiconducting substrate comprises AlGaAs, and wherein the second semiconducting substrate comprises GaAs.

Aspect 4. The photodetector of Aspect 2, wherein the first semiconducting substrate has a bandgap energy (Eg) greater than a bandgap energy (Eg) of the second semiconducting substrate.

Aspect 5. The photodetector of any one of Aspects 1-4, wherein (a) the contact between the first portion of MXene material and the first surface of the first semiconducting substrate is characterized as a Schottky contact, or (b) wherein the contact between the second portion of MXene material and the first surface of the first semiconducting substrate is characterized as a Schottky contact, or both (a) and (b).

Aspect 6. The photodetector of any one of Aspects 1-5, wherein (a) the contact between the first portion of MXene material and the first surface of the first semiconducting substrate is characterized as a ohmic contact, or (b) wherein the contact between the second portion of MXene material and the first surface of the first semiconducting substrate is characterized as a ohmic contact, or both (a) and (b).

Aspect 7. The photodetector of any one of Aspects 1-6, wherein one of the contact between the first portion of MXene material and the first surface of the first semiconducting substrate and the contact between the second portion of MXene material and the first surface of the first semiconducting substrate is characterized as a Schottky contact and the other of the contacts is characterized as an ohmic contact.

Aspect 8. The photodetector of any one of Aspects 1-7, wherein the distance is in the range of from about 0.1 to about 50 micrometers.

Aspect 9. The photodetector of Aspect 8, wherein the distance is in the range of from about 5 to about 30 micrometers.

Aspect 10. The photodetector of any one of Aspects 1-9, wherein the first portion of MXene material and the second portion of MXene material comprise different MXene materials.

Aspect 11. The photodetector of any one of Aspects 1-10, further comprising a voltage source configured to apply a bias voltage to the assembly.

Aspect 12. The photodetector of any one of Aspects 1-11, further comprising a monitor configured to collect a photocurrent of the assembly related to illumination of the assembly.

Aspect 13. The photodetector of any one of Aspects 1-12, wherein at least one of the first portion of MXene material and the second portion of MXene material is characterized as essentially transparent to visible light.

Aspect 14. The photodetector of any one of Aspects 1-13, wherein at least one of the first portion of MXene material and the second portion of MXene material defines a thickness in the range of from about 5 nm to about 50 nm.

Aspect 15. The photodetector of any one of Aspects 1-14, wherein the surface of the substrate defines an area available to receive illumination, and wherein the first portion of MXene material and the second portion of MXene material occlude, in total, from about 1% to about 99% of the area.

Aspect 16. The photodetector of Aspect 15, wherein the first portion of MXene material and the second portion of MXene material occlude, in total, from about 50% to about 99% of the area.

Aspect 17. The photodetector of Aspect 16, wherein the first portion of MXene material and the second portion of MXene material occlude, in total, from about 80% to about 99% of the area.

Aspect 18. A method, comprising collecting a photocurrent from a photodetector according to any one of Aspects 1-17.

Aspect 19. A method, comprising:
disposing a MXene material onto a surface of a semiconductor substrate so as to define a first region of the MXene material and a second region of the MXene material, the first region of the MXene material being separated from the second region of the MXene material by a distance in the range of from about 0.1 to about 50 micrometers.

Aspect 20. The method of Aspect 19, wherein the disposing comprises spin casting the MXene material.

Aspect 21. The method of any one of Aspects 19-20, wherein the first region of the MXene material and a second region of the MXene material conform to one or more features of a mask.

Aspect 22. The method of Aspect 21, further comprising defining the one or more features of the mask.

Aspect 23. The method of any one of Aspects 19-22, further comprising placing a current collector into electronic communication with the semiconductor substrate.

Aspect 24. The method of any one of Aspects 19-23, further comprising disposing the semiconductor, the first region of MXene material, and the second region of the MXene material such that the semiconductor, the first region of MXene material, and the second region of the MXene material are disposed to receive filtered or unfiltered ambient illumination.

Aspect 25. A polarizer, comprising:
a substrate;
a plurality of parallel elongate MXene portions disposed on the substrate;
the MXene portions having an average width and being arranged in an essentially periodic pattern,
and adjacent MXene portions being separated from one another by an average separation distance of from about 0.1 to about 100 micrometers, e.g., from about 0.1 to about 100 micrometers, from about 1 to about 90 micrometers, from about 2 to about 80micrometers, from about 4 to about 70 micrometers, from about 6 to about 60 micrometers, from about 10 about 50 micrometers, or from about 15 to about 30 micrometers. The MXene portions can be superposed on a semiconductor substrate (or assembly of such substrates) described elsewhere within the present disclosure.

Aspect 26. The polarizer of Aspect 25, wherein the MXene portions define an average thickness of from about 10 nm to about 5 micrometers.

Aspect 27. The polarizer of any one of Aspects 25-26, wherein the MXene portions define an average width of from about 0.1 to about 100 micrometers, e.g., from about 0.1 to about 100 micrometers, from about 1 to about 90 micrometers, from about 2 to about 80 micrometers, from about 4 to about 70 micrometers, from about 6 to about 60 micrometers, from about 10 about 50 micrometers, or from about 15 to about 30 micrometers.

Aspect 28. The polarizer of any one of Aspects 25-27, wherein adjacent MXene portions are separated from one another by an average distance of from about 5 micrometers to about 50 micrometers.

Aspect 29. The polarizer of any one of Aspects 25-28, wherein the substrate is quartz.

Aspect 30. The polarizer of any one of Aspects 25-29, wherein the average width of the MXene portions is greater than the average separation distance of the MXene portions.

Aspect 31. The polarizer of any one of Aspects 25-30, wherein the average width of the MXene portions is less than the average separation distance of the MXene portions.

Aspect 32. A method, comprising communicating a signal to a polarizer according to any one of Aspects 25-31.

Aspect 33. A method, comprising:
disposing a MXene material onto a surface of a semiconductor substrate so as to define a plurality of parallel elongate MXene portions disposed on the substrate;
the MXene portions having an average width and being arranged in an essentially periodic pattern,
and adjacent MXene portions being separated from one another by an average separation distance of from about 0.1 to about 100 micrometers.

Aspect 34. The method of Aspect 33, wherein the disposing comprises spin casting the MXene material.

Aspect 35. The method of any one of Aspects 33-34, wherein the first region of the MXene material and a second region of the MXene material conform to one or more features of a mask.

Aspect 36. The method of Aspect 35, further comprising defining the one or more features of the mask.

Aspect 37. The method of any one of Aspects 33-36, further comprising placing a current collector into electronic communication with the semiconductor substrate.

Aspect 38. The method of any one of Aspects 33-37, further comprising disposing the semiconductor, the first region of MXene material, and the second region of the MXene material such that the semiconductor, the first region of MXene material, and the second region of the MXene material are disposed to receive a signal.

Aspect 39. A metal semiconductor field effect transistor, comprising:
a source electrode;
a drain electrode; and
a gate electrode,
a resistive path channel being defined between the source electrode and the gate electrode,
the gate electrode comprising a MXene material configured to perform as a rectifying Schottky contact,
the MXene material of the gate electrode being essentially transparent, and
the metal semiconductor field effect transistor being configured as an optical field effect transistor controllable by illumination of the MXene material.

Any one or more of the source, drain, and gate electrodes can be a MXene material.

Aspect 40. A high electron mobility field effect transistor, comprising:
a source electrode;
a drain electrode;
a gate electrode; and
a resistive path channel being defined between the source electrode and the
gate electrode, the resistive path channel comprising a heterojunction within which are confined 2-D electron gases,
the gate electrode comprising a MXene material configured to perform as a rectifying Schottky contact.
the MXene material being essentially transparent, and
the high electron mobility field effect transistor being configured as an optical field effect transistor controllable by illumination of the MXene material; and
a first semiconducting substrate on which the gate electrode is superposed,
optionally a second semiconducting substrate on which the first semiconducting substrate is disposed, the second semiconducting substrate defining a heterojunction with the first semiconducting substrate and the first semiconducting substrate has a bandgap energy (Eg) greater than a bandgap energy (Eg) of the second semiconducting substrate.

Aspect 42. The metal semiconductor field effect transistor of Aspect 41, wherein the first semiconducting substrate comprises AlGaAs, and wherein the second semiconducting substrate comprises GaAs

Aspect 41. A metal oxide semiconductor field effect transistor, comprising:
a source electrode;
a drain electrode;
a gate electrode; and
a resistive path channel being defined between the source electrode and the gate electrode,
one or more of the source electrode, the gate electrode, and the drain electrode comprising a MXene material configured to perform as an ohmic contact,
the MXene material optionally being essentially transparent; and
a first semiconducting substrate on which the gate electrode is superposed,
optionally a second semiconducting substrate on which the first semiconducting substrate is disposed, the second semiconducting substrate defining a heterojunction with the first semiconducting substrate and the first semiconducting substrate has a bandgap energy (Eg) greater than a bandgap energy (Eg) of the second semiconducting substrate.

### References

The following references are provided for the reader's convenience; their listing here is not an acknowledgment that they are material to the patentability of the technology described herein.
Jepsen, P. U.; Cooke, D. G.; Koch, M., Terahertz spectroscopy and imaging-Modern techniques and applications. Laser & Photonics Reviews 2011, 5(1), 124-166.
Kürner, T.; Priebe, S., Towards THz Communications—Status in Research, Standardization and Regulation. Journal of Infrared, Millimeter, and Terahertz Waves 2014, 35(1), 53-62.
Ma, J.; Shrestha, R.; Adelberg, J.; Yeh, C.-Y.; Hossain, Z.; Knightly, E.; Jornet, J. M.; Mittleman, D. M., Security and eavesdropping in terahertz wireless links. Nature 2018, 563(7729), 89-93.
Mittleman, D. M., Frontiers in terahertz sources and plasmonics. Nature Photonics 2013, 7 (9), 666-669.
Tonouchi, M., Cutting-edge terahertz technology. Nature photonics 2007, 1 (2), 97-105.
Yan, F.; Yu, C.; Park, H.; Parrott, E. P. J.; Pickwell-MacPherson, E., Advances in Polarizer Technology for Terahertz Frequency Applications. Journal of Infrared, Millimeter, and Terahertz Waves 2013, 34(9), 489-499.
Yamada, I.; Takano, K.; Hangyo, M.; Saito, M.; Watanabe, W., Terahertz wire-grid polarizers with micrometer-pitch Al gratings. Opt. Lett. 2009, 34(3), 274-276.
Huang, Z.; Parrott, E. P. J.; Park, H.; Chan, H. P.; Pickwell-MacPherson, E., High extinction ratio and low transmission loss thin-film terahertz polarizer with a tunable bilayer metal wire-grid structure. Opt. Lett. 2014, 39(4), 793-796.
Partanen, A.; Väyrynen, J.; Hassinen, S.; Tuovinen, H.; Mutanen, J.; Itkonen, T.; Silfsten, P.; Pääkkönen, P.; Kuittinen, M.; Mönkkönen, K.; Venäläinen, T., Fabrication of terahertz wire-grid polarizers. Appl. Opt. 2012, 51(35), 8360-8365.
Deng, L. Y.; Teng, J. H.; Zhang, L.; Wu, Q. Y.; Liu, H.; Zhang, X. H.; Chua, S. J., Extremely high extinction ratio terahertz broadband polarizer using bilayer subwavelength metal wire-grid structure. Appl. Phys. Lett. 2012, 101(1), 011101
Takano, K.; Yokoyama, H.; Ichii, A.; Morimoto, I.; Hangyo, M., Wire-grid polarizer sheet in the terahertz region fabricated by nanoimprint technology. Opt. Lett. 2011, 36(14), 2665-2667.
Ferraro, A.; Zografopoulos, D. C.; Missori, M.; Peccianti, M.; Caputo, R.; Beccherelli, R., Flexible terahertz wire grid polarizer with high extinction ratio and low loss. Opt. Lett. 2016, 41(9), 2009-2012.
Ren, L.; Pint, C. L.; Arikawa, T.; Takeya, K.; Kawayama, I.; Tonouchi, M.; Hauge, R. H.; Kono, J., Broadband terahertz polarizers with ideal performance based on aligned carbon nanotube stacks. Nano Lett. 2012, 12(2), 787-90.
Ren, L.; Pint, C. L.; Booshehri, L. G.; Rice, W. D.; Wang, X.; Hilton, D. J.; Takeya, K.; Kawayama, I.; Tonouchi, M.; Hauge, R. H.; Kono, J., Carbon Nanotube Terahertz Polarizer. Nano Lett. 2009, 9(7), 2610-2613.
Kyoung, J.; Jang, E. Y.; Lima, M. D.; Park, H.-R.; Robles, R. O.; Lepro, X.; Kim, Y. H.; Baughman, R. H.; Kim, D.-S., A Reel-Wound Carbon Nanotube Polarizer for Terahertz Frequencies. Nano Lett. 2011, 11(10), 4227-4231.
Xiang, W.; Huang, X.; Li, D.; Zhou, Q.; Guo, H.; Li, J., High extinction ratio terahertz broadband polarizer based on the aligned Ni nanowire arrays. Opt. Lett. 2020, 45(7), 1978-1981.
Baig, S. A.; Boland, J. L.; Damry, D. A.; Tan, H. H.; Jagadish, C.; Joyce, H. J.; Johnston, M. B., An Ultrafast Switchable Terahertz Polarization Modulator Based on III-V Semiconductor Nanowires. Nano Lett. 2017, 17(4), 2603-2610.
Naguib, M.; Kurtoglu, M.; Presser, V.; Lu, J.; Niu, J.; Heon, M.; Hultman, L.; Gogotsi, Y.; Barsoum, M. W., Two Dimensional Nanocrystals Produced by Exfoliation of Ti3AlC2. Advan. Mater. 2011, 23, 4248-4253.
Naguib, M.; Mashtalir, O.; Carle, J.; Lu, J.; Hultman, L.; Gogotsi, Y.; Barsoum, M. W., Two-Dimensional Transition Metal Carbides. ACS Nano 2012, 6, 1322-1331.
Naguib, M.; Mashtalir, O.; Carle, J.; Presser, V.; Lu, J.; Hultman, L.; Gogotsi, Y.; Barsoum, M. W., Two-Dimensional Transition Metal Carbides. ACS Nano 2012, 6(2), 1322-1331.
Verger, L.; Natu, V.; Carey, M.; Barsoum, M. W., MXenes: An Introduction of Their Synthesis, Select Properties, and Applications. Trends in Chemistry 2019.
Anasori, B.; Xie, Y.; Beidaghi, M.; Lu, J.; Hosler, B. C.; Hultman, L.; Kent, P. R. C.; Gogotsi, Y.; Barsoum, M. W., Two-Dimensional, Ordered, Double Transition Metals Carbides (MXenes). ACS Nano 2015, 9(10), 9507-9516.
Khazaei, M.; Mishra, A.; Venkataramanan, N. S.; Singh, A. K.; Yunoki, S., Recent advances in MXenes: From fundamentals to applications. Curr. Opin. Solid State Mater. Sci. 2019, 23(3), 164-178.
Naguib, M.; Mochalin, V. N.; Barsoum, M. W.; Gogotsi, Y., 25th Anniversary Article: MXenes: A New Family of Two-Dimensional Materials. Adv. Mater. 2014, 26(7), 992-1005.
Choi, G.; Shahzad, F.; Bahk, Y. M.; Jhon, Y. M.; Park, H.; Alhabeb, M.; Anasori, B.; Kim, D. S.; Koo, C. M.; Gogotsi, Y.; Seo, M., Enhanced Terahertz Shielding of MXenes with Nano-Metamaterials. Advanced Optical Materials 2018, 6(5), 1701076.
Dillon, A. D.; Ghidiu, M. J.; Krick, A. L.; Griggs, J.; May, S. J.; Gogotsi, Y.; Barsoum, M. W.; Fafarman, A. T., Highly Conductive Optical Quality Solution-Processed Films of 2D Titanium Carbide. Adv. Funct. Mater. 2016, 26(23), 4162-4168.
Feng, W.; Luo, H.; Wang, Y.; Zeng, S.; Deng, L.; Zhou, X.; Zhang, H.; Peng, S., Ti3C2 MXene: a promising microwave absorbing material. RSC Advances 2018, 8 (5), 2398-2403.
Jhon, Y. I.; Seo, M.; Jhon, Y. M., First-principles study of a MXene terahertz detector. Nanoscale 2018, 10(1), 69-75.
Shahzad, F.; Alhabeb, M.; Hatter, C. B.; Anasori, B.; Man Hong, S.; Koo, C. M.; Gogotsi, Y., Electromagnetic interference shielding with 2D transition metal carbides (MXenes). Science 2016, 353 (6304), 1137-1140.
Zhang, C.; Anasori, B.; Seral-Ascaso, A.; Park, S. H.; McEvoy, N.; Shmeliov, A.; Duesberg, G. S.; Coleman, J. N.; Gogotsi, Y.; Nicolosi, V., Transparent, Flexible, and Conductive 2D Titanium Carbide (MXene) Films with High Volumetric Capacitance. Adv. Mater. 2017, 29 (36), 1702678.
Li, G.; Amer, N.; Hafez, H. A.; Huang, S.; Turchinovich, D.; Mochalin, V. N.; Hegmann, F. A.; Titova, L. V., Dynamical Control over Terahertz Electromagnetic Interference Shielding with 2D Ti3C2Ty MXene by Ultrafast Optical Pulses. Nano Lett. 2019.
Li, G.; Kushnir, K.; Dong, Y.; Chertopalov, S.; Rao, A. M.; Mochalin, V. N.; Podila, R.; Titova, L. V., Equilibrium and non-equilibrium free carrier dynamics in 2D Ti 3 C 2 T x MXenes: THz spectroscopy study. 2D Materials 2018, 5 (3), 035043.
Hu, H.; Hua, T., An easily manipulated protocol for patterning of MXenes on paper for planar micro-supercapacitors. Journal of Materials Chemistry A 2017, 5 (37), 19639-19648.
Xu, B.; Zhu, M.; Zhang, W.; Zhen, X.; Pei, Z.; Xue, Q.; Zhi, C.; Shi, P., Ultrathin MXene-Micropattern-Based Field-Effect Transistor for Probing Neural Activity. Adv. Mater. 2016, 28 (17), 3333-3339.
Montazeri, K.; Currie, M.; Verger, L.; Dianat, P.; Barsoum, M. W.; Nabet, B., Beyond Gold: Spin-Coated Ti3C2-Based MXene Photodetectors. Adv. Mater. 2019, 31 (43), 1903271.
Grischkowsky, D.; Keiding, S.; van Exter, M.; Fattinger, C., Far-infrared time-domain spectroscopy with terahertz beams of dielectrics and semiconductors. Journal of the Optical Society of America B 1990, 7 (10), 2006-2015.
Smith, N., Classical generalization of the Drude formula for the optical conductivity. Physical Review B 2001, 64 (15).
Cocker, T. L.; Baillie, D.; Buruma, M.; Titova, L. V.; Sydora, R. D.; Marsiglio, F.; Hegmann, F. A., Microscopic origin of the Drude-Smith model. Physical Review B 2017, 96 (20), 205439.
Li, G.; Natu, V.; Shi, T.; Barsoum, M. W.; Titova, L. V., Two-Dimensional MXenes Mo2Ti2C3Tz and Mo2TiC2Tz: Microscopic Conductivity and Dynamics of Photoexcited Carriers. ACS Applied Energy Materials 2020.
Hu, T.; Zhang, H.; Wang, J.; Li, Z.; Hu, M.; Tan, J.; Hou, P.; Li, F.; Wang, X., Anisotropic electronic conduction in stacked two-dimensional titanium carbide. Scientific Reports 2015, 5, 16329.
C. Burrus, J. Bowers, R. Tucker, Electron. Lett. 1985, 21, 262.
C. Lenox, H. Nie, P. Yuan, G. Kinsey, A. Homles, B. Streetman, J. Campbell, IEEE Photonics Technol. Lett. 1999, 11, 1162.
T. Sugeta, T. Urisu, S. Sakata, Y. Mizushima, Jpn. J. Appl. Phys. 1980, 19, 459.
S. Assefa, F. Xia, S. W. Bedell, Y. Zhang, T. Topuria, P. M. Rice, Y. A. Vlasov, Opt. Express 2010, 18, 4986.
F. Koppens, T. Mueller, P. Avouris, A. Ferrari, M. Vitiello, M. Polini, Nat. Nanotechnol. 2014, 9, 780.
C. H. Liu, Y. C. Chang, T. B. Norris, Z. Zhong, Nat. Nanotechnol. 2014, 9, 273.
T. Mueller, F. Xia, P. Avouris, Nat. Photonics 2010, 4, 297.
P. Tassin, T. Koschny, M. Kafesaki, C. M. Soukoulis, Nat. Photonics 2012, 6, 259.
G. B. Tait, B. Nabet, IEEE Trans. Electron Devices 2003, 50, 2573.
J. Song, M. Lim, S. S. Lee, B. J. Lee, Phys. Rev. Appl. 2019, 11, 044040.
L. C. Liou, B. Nabet, Appl. Opt. 1996, 35, 15.
A. Anwar, B. Nabet, in 1999 SBMO/IEEE MTT-S Int. Microwave and Optoelectronics Conf., IEEE, Piscataway, NJ, USA 1999, pp. 581-584.
B. Nabet, M. Currie, P. Dianat, F. Quaranta, A. Cola, ACS Photonics 2014, 1, 560.
R. J. Shiue, Y. Gao, Y. Wang, C. Peng, A. D. Robertson, D. K. Efetov, S. Assefa, F. H. Koppens, J. Hone, D. Englund, Nano Lett. 2015, 15, 7288.
B. Nabet, Photodetectors: Materials, Devices and Applications in Communications and Imaging Technologies, Elsevier Science & Technology, Oxford, UK 2015.
M. Naguib, M. Kurtoglu, V. Presser, J. Lu, J. Niu, M. Heon, L. Hultman, Y. Gogotsi, M. W. Barsoum, Adv. Mater. 2011, 23, 4248.
M. Sokol, V. Natu, S. Kota, M. W. Barsoum, Trends Chem. 2019, 1, 210.
J. Halim, K. M. Cook, M. Naguib, P. Eklund, Y. Gogotsi, J. Rosen, M. W. Barsoum, Appl. Surf. Sci. 2016, 362, 406.
M. Li, J. Lu, K. Luo, Y. Li, K. Chang, K. Chen, J. Zhou, J. Rosen, L. Hultman, P. Eklund, J. Am. Chem. Soc. 2019, 141, 4730.
M. Naguib, V. N. Mochalin, M. W. Barsoum, Y. Gogotsi, Adv. Mater. 2014, 26, 992.
M. Khazaei, A. Ranjbar, M. Arai, T. Sasaki, S. Yunoki, J. Mater. Chem. C 2017, 5, 2488.
B. Anasori, M. R. Lukatskaya, Y. Gogotsi, Nat. Rev. Mater. 2017, 2, 16098.
J. Pang, R. G. Mendes, A. Bachmatiuk, L. Zhao, H. Q. Ta, T. Gemming, H. Liu, Z. Liu, M. H. Rummeli, Chem. Soc. Rev. 2019, 48, 72.
K. Hantanasirisakul, Y. Gogotsi, Adv. Mater. 2018, 30, 1804779.
L. Verger, C. Xu, V. Natu, H. M. Cheng, W. Ren, M. W. Barsoum, Curr. Opin. Solid State Mater. Sci. 2019, 23, 149.
B. Dyatkin, E. Mamontov, K. M. Cook, Y. Gogotsi, Prog. Nat. Sci.: Mater. Int. 2015, 25, 631.
A. S. Levitt, M. Alhabeb, C. B. Hatter, A. Sarycheva, G. Dion, Y. Gogotsi, J. Mater. Chem. A 2019, 7, 269.
N. Kurra, B. Ahmed, Y. Gogotsi, H. N. Alshareef, Adv. Energy Mater. 2016, 6, 1601372.
Y. Jhon, M. Seo, Y. Jhon, Nanoscale 2018, 10, 69.
Y. Liu, H. Xiao, W. A. Goddard III, J. Am. Chem. Soc. 2016, 138, 15853.
P. Zhao, H. Jin, X. Lv, B. Huang, Y. Ma, Y. Dai, Phys. Chem. Chem. Phys. 2018, 20, 16551.
A. Sarycheva, A. Polemi, Y. Liu, K. Dandekar, B. Anasori, Y. Gogotsi, Sci. Adv. 2018, 4, eaau0920.
S. Bae, H. Kim, Y. Lee, X. Xu, J. S. Park, Y. Zheng, J. Balakrishnan, T. Lei, H. R. Kim, Y. I. Song, Nat. Nanotechnol. 2010, 5, 574.
X. Wang, L. Zhi, K. Müllen, Nano Lett. 2008, 8, 323.
J. Wu, M. Agrawal, H. A. Becerril, Z. Bao, Z. Liu, Y. Chen, P. Peumans, ACS Nano 2009, 4, 43.
G. Ying, A. D. Dillon, A. T. Fafarman, M. W. Barsoum, Mater. Res. Lett. 2017, 5, 391.
J. Halim, M. R. Lukatskaya, K. M. Cook, J. Lu, C. R. Smith, L.-Å. Näslund, S. J. May, L. Hultman, Y. Gogotsi, P. Eklund, Chem. Mater. 2014, 26, 2374.
A. D. Dillon, M. J. Ghidiu, A. L. Krick, J. Griggs, S. J. May, Y. Gogotsi, M. W. Barsoum, A. T. Fafarman, Adv. Funct. Mater. 2016, 26, 4162.
H. Hu, T. Hua, J. Mater. Chem. A 2017, 5, 19639.
B. Xu, M. Zhu, W. Zhang, X. Zhen, Z. Pei, Q. Xue, C. Zhi, P. Shi, Adv. Mater. 2016, 28, 3333.
W. Zheng, T. Xie, Y. Zhou, Y. Chen, W. Jiang, S. Zhao, J. Wu, Y. Jing, Y. Wu, G. Chen, Nat. Commun. 2015, 6, 6972.
S. Binari, M. Marchywka, D. Koolbeck, H. Dietrich, D. Moses, Diamond Relat. Mater. 1993, 2, 1020.
C. V. Poulton, A. Yaacobi, D. B. Cole, M. J. Byrd, M. Raval, D. Vermeulen, M. R. Watts, Opt. Lett. 2017, 42, 4091.
R. Pasqualotto, P. Nielsen, Rev. Sci. Instrum. 2003, 74, 1671.
X. Gong, M. Tong, Y. Xia, W. Cai, J. S. Moon, Y. Cao, G. Yu, C. L. Shieh, B. Nilsson, A. J. Heeger, Science 2009, 325, 1665.
G. Konstantatos, Nat. Commun. 2018, 9, 5266.
N. Driscoll, A. G. Richardson, K. Maleski, B. Anasori, O. Adewole, P. Lelyukh, L. Escobedo, D. K. Cullen, T. H. Lucas, Y. Gogotsi, ACS Nano 2018, 12, 10419.
M. Thunemann, Y. Lu, X. Liu, K. Kiliç, M. Desjardins, M. Vandenberghe, S. Sadegh, P. A. Saisan, Q. Cheng, K. L. Weldy, Nat. Commun. 2018, 9, 2035.
A. D. Dillon, M. J. Ghidiu, A. L. Krick, J. Griggs, S. J. May, Y. Gogotsi, M. W. Barsoum, A. T. Fafarman, Highly Conductive Optical Quality Solution-Processed Films of 2D Titanium Carbide. Adv. Funct. Mater. 2016, 26, 4162-4168.
G. Ying, S. Kota, A. D. Dillon, A. T. Fafarman, M. W. Barsoum, Conductive transparent V2CTx (MXene) films. FlatChem 2018, 8, 25-30.
M. Ghidiu, M. R. Lukatskaya, M. Q. Zhao, Y. Gogotsi, M. W. Barsoum, Conductive two-dimensional titanium carbide “clay” with high volumetric capacitance. Nature 2014, 516, 78.
S. M. Sze, K. K. Ng, Physics of semiconductor devices; John Wiley & sons, 2006.
L. C. Liou, B. Nabet, Simple analytical model of bias dependence of the photocurrent of metal-semiconductor-metal photodetectors. Appl Opt. 1996, 35, 15-23.
Currie, M., et al, Performance Enhancement of a GaAs Detector with a Vertical Field and an Embedded Thin Low-Temperature Grown Layer, Sensors, 2013, 13, 2475-2483.

What is claimed:

1. A photodetector, comprising:
an assembly that comprises (i) a first semiconducting substrate having a first surface and a second surface; (ii) a first portion of MXene material superposed on a first surface of the semiconducting substrate so as to define a contact between the first portion of MXene material and the first surface of the first semiconducting substrate; and (iii) a second portion of MXene material superposed on the first surface of the first semiconducting substrate so as to define a contact between the second portion of MXene material and the first surface of the first semiconducting substrate,
the first portion of MXene material and the second portion of MXene material being separated from one another by a distance.

2. The photodetector of claim 1, further comprising a second semiconducting substrate superposed on the second surface of the first semiconducting substrate, the second semiconducting substrate defining a heterojunction with the first semiconducting substrate.

3. The photodetector of claim 2, wherein the first semiconducting substrate comprises AlGaAs, and wherein the second semiconducting substrate comprises GaAs.

4. The photodetector of claim 2, wherein the first semiconducting substrate has a bandgap energy (Eg) greater than a bandgap energy (Eg) of the second semiconducting substrate.

5. The photodetector of claim 1, wherein (a) the contact between the first portion of MXene material and the first surface of the first semiconducting substrate is characterized as a Schottky contact, or (b) wherein the contact between the second portion of MXene material and the first surface of the first semiconducting substrate is characterized as a Schottky contact, or both (a) and (b).

6. The photodetector of claim 1, wherein (a) the contact between the first portion of MXene material and the first surface of the first semiconducting substrate is characterized as a ohmic contact, or (b) wherein the contact between the second portion of MXene material and the first surface of the first semiconducting substrate is characterized as a ohmic contact, or both (a) and (b).

7. The photodetector of claim 1, wherein one of the contact between the first portion of MXene material and the first surface of the first semiconducting substrate and the contact between the second portion of MXene material and the first surface of the first semiconducting substrate is characterized as a Schottky contact and the other of the contacts is characterized as an ohmic contact.

8. The photodetector of claim 1, wherein the distance is in the range of from about 0.1 to about 50 micrometers.

9. The photodetector of claim 1, wherein the first portion of MXene material and the second portion of MXene material comprise different MXene materials.

10. The photodetector of claim 1, further comprising a voltage source configured to apply a bias voltage to the assembly.

11. The photodetector of claim 1, further comprising a monitor configured to collect a photocurrent of the assembly related to illumination of the assembly.

12. The photodetector of claim 1, wherein at least one of the first portion of MXene material and the second portion of MXene material is characterized as essentially transparent to visible light.

13. The photodetector of claim 1, wherein at least one of the first portion of MXene material and the second portion of MXene material defines a thickness in the range of from about 5 nm to about 50 nm.

14. The photodetector of claim 1, wherein the surface of the substrate defines an area available to receive illumination, and wherein the first portion of MXene material and the second portion of MXene material occlude, in total, from about 1% to about 99% of the area.

15. A method, comprising collecting a photocurrent from a photodetector according to claim 1.

16. A polarizer, comprising:
a substrate;
a plurality of parallel elongate MXene portions disposed on the substrate;
the MXene portions having an average width and being arranged in an essentially periodic pattern,
and adjacent MXene portions being separated from one another by an average separation distance of from about 0.1 micrometers to about 100 micrometers, and
the MXene portions optionally defining an average thickness of from about 10 nm to about 5 micrometers.

17. A metal semiconductor field effect transistor, comprising:
a source electrode;
a drain electrode; and
a gate electrode,
a resistive path channel being defined between the source electrode and the gate electrode,
the gate electrode comprising a MXene material configured to perform as a rectifying Schottky contact,
the MXene material of the gate electrode being essentially transparent, and
the metal semiconductor field effect transistor being configured as an optical field effect transistor controllable by illumination of the MXene material; and
a first semiconducting substrate on which the gate electrode is superposed,
optionally a second semiconducting substrate on which the first semiconducting substrate is disposed, the second semiconducting substrate defining a heterojunction with the first semiconducting substrate and the first semiconducting substrate has a bandgap energy (Eg) greater than a bandgap energy (Eg) of the second semiconducting substrate.

18. The metal semiconductor field effect transistor of claim 17, wherein the first semiconducting substrate comprises AlGaAs, and wherein the second semiconducting substrate comprises GaAs.

19. A high electron mobility field effect transistor, comprising:
a source electrode;
a drain electrode;
a gate electrode; and
a resistive path channel being defined between the source electrode and the gate electrode, the resistive path channel comprising a heterojunction,
the gate electrode comprising a MXene material configured to perform as a rectifying Schottky contact,
the MXene material being essentially transparent, and
the high electron mobility field effect transistor being configured as an optical field effect transistor controllable by illumination of the MXene material; and
a first semiconducting substrate on which the gate electrode is superposed,
optionally a second semiconducting substrate on which the first semiconducting substrate is disposed, the second semiconducting substrate defining a heterojunction with the first semiconducting substrate and the first semiconducting substrate has a bandgap energy (Eg) greater than a bandgap energy (Eg) of the second semiconducting substrate.

20. A metal oxide semiconductor field effect transistor, comprising:
a source electrode;
a drain electrode;
a gate electrode; and
a resistive path channel being defined between the source electrode and the gate electrode,
one or more of the source electrode, the gate electrode, and the drain electrode comprising a MXene material configured to perform as an ohmic contact,
the MXene material optionally being essentially transparent; and
a first semiconducting substrate on which the gate electrode is superposed,
optionally a second semiconducting substrate on which the first semiconducting substrate is disposed, the second semiconducting substrate defining a heterojunction with the first semiconducting substrate and the first semiconducting substrate has a bandgap energy (Eg) greater than a bandgap energy (Eg) of the second semiconducting substrate.
